(19) United States
(12) Patent Application Publication
(10) Pub. No.: US 2004/0244675 A1
(43) Pub. Date: Dec. 9, 2004

(54) Non-magnetic particles having a plate shape and method for production thereof, abrasive material, polishing article and abrasive fluid comprising such particles

(76) Inventors: Mikio Kishimoto, Ibaraki (JP); Nobuko Kasajima, Kyoto (JP); Yuko Sawaki, Kyoto (JP); Kimihiko Kaneno, Kyoto (JP); Yasumori Maeda, Osaka (JP)

Correspondence Address: BIRCH STEWART KOLASCH & BIRCH, PO BOX 747, FALLS CHURCH, VA, 22040-0747, US

(21) Appl. No.: 10/490,630

(22) PCT Filed: Aug. 9, 2002
(86) PCT No.: PCT/JP02/08171

(51) Int. Cl. C30B 23/00; C30B 25/00; C30B 28/12; C30B 28/14

(52) U.S. Cl. 117/84

(57) ABSTRACT

Non-magnetic particles, in particular, of an oxide such as cerium oxide, zirconium oxide, aluminum oxide, silicon oxide or iron oxide which have the shape of a plate and have an average particle diameter in the direction of the plate surface in a range of 10 to 100 nm; and a method for producing the above non-magnetic particles of the oxide which comprises adding a salt of the above element to an aqueous alkaline solution to provide a hydroxide or hydrate thereof, heating the hydroxide or hydrate in the presence of water at a temperature in the range of 110 to 300° C., followed by filtration and drying, and further heating the resultant product in air at a temperature in the range of 300 to 1200° C., to thereby produce particles of the oxide. The above non-magnetic particles, in particular, of on oxide has a narrow distribution of particle diameter, is extremely reduced in sintering or coagulation, and exhibits good crystallinity.

### FIELD OF THE INVENTION

The present invention relates to non-magnetic plate-form particles having a novel particle shape, which are useful as an abrasive for an abrasive member or an abrasive liquid, as an additive to coating type recording media, or as an additive to functional films such as optical films, and a method for producing such non-magnetic plate-form particles and the applications thereof. In particular, the present invention relates to non-magnetic particles of cerium oxide, zirconium oxide, aluminum oxide, silicon oxide, iron oxide, etc., which have a novel particle shape and a specific particle size.

### BACKGROUND ART

Non-magnetic particles such as cerium oxide particles, zirconium oxide particles, aluminum oxide particles, silicon oxide particles, iron oxide particles, etc. are used in a wide variety of applications, for example, as abrasives of abrasive members such as abrasive sheets, abrasive films, abrasive tapes, abrasive tools, etc., or abrasive liquids, as additives to various coating type recording media, and the like.

Cerium oxide, zirconium oxide, aluminum oxide and silicon oxide are preferably used in applications which require high abrading rates, since they have high Mohs' hardness, while iron oxide is preferably used in applications which require mild abrasion.

For producing such non-magnetic oxide particles, various methods are known.

(1) Cerium Oxide

Cerium oxide particles are usually prepared by milling cerium oxide, which is produced sintering, with a ball mill, etc. to obtain fine particles. However, the cerium oxide particles prepared by such a method has a broad particle size distribution. In addition, since the particles are mechanically ground, the lower limit of the particle size is in a submicron order and it is difficult to further decrease the particle size.

Apart from the above method, it is also known that a cerium salt such as cerium carbonate is thermally oxidized in an air to obtain cerium oxide particles. This method has an advantage over the milling method in that the finer particle scan be easily obtained. However, the particles tend to be sintered together, and thus it is difficult to uniformly disperse the particles in a liquid medium when they are used in an abrasive liquid.

For example, JP-A-10-106990 and JP-A-11-181405 heat cerium carbonate in an air to obtain cerium oxide, and then mechanically mill cerium oxide to obtain fine particles. In the former patent application, JP-A-10-106990, cerium oxide is milled with a ball mill, and the resulting particles have a primary particle size of 200 nm. The particle shape of cerium oxide prior to ball milling is spherical. According to the latter patent application JP-A-11-181405, after sintering, the cerium oxide particles are jet milled to decrease the particle size. However, the resulting cerium oxide particles contain unmilled particles having a large particle size of 1 to 3 μm and 0.5 to 1 μm besides small particles having a particle size corresponding to a primary particle size.

JP-A-9-27042 discloses a method for preparing cerium oxide particles comprising ball milling cerium carbonate as a raw material and thermally treating the milled material in an air. As described in this patent application, the cerium oxide particles prepared by this method have a primary particle size of 20 nm but contain secondary particles having a size of 0.2 to 0.3 μm. The particle shape is not described in detail. For example, JP-A-10-102039 describes that an aspect ratio is from 1 to 2. A particle having such an aspect ratio is close to a granule or a particle rather than a plate.

As described above, since the conventional methods essentially use mechanical grinding to decrease the particle sizes, particles having a specific particle shape cannot be obtained, and those having a narrow particle size distribution are hardly obtained. Furthermore, since mechanical impact is applied to the particles, the cerium oxide particles tend to be distorted so that their crystallinity may be deteriorated. The crystallinity of cerium oxide particles is very important when they are used as an abrasive. Although the conventional cerium oxide particles may have a spectrum assigned to cerium oxide in an X-ray diffraction analysis, they are not satisfactory in their crystallinity as the abrasive.

Usually, the cerium oxide particles tend to contain elements other than cerium, which are contained in a raw material. That is, it is difficult to obtain high purity cerium oxide. The purity of cerium oxide is important, particularly when the cerium oxide particles are used in the form of a chemical polishing liquid.

(2) Zirconium Oxide

Zirconium oxide particles are used as an abrasive of an abrasive sheet, an abrasive liquid, etc., and the zirconium oxide particles used as the abrasive are often produced by grinding a zirconium oxide ingot to obtain fine particles. When the fine particles are produced with mechanical means, the lower limit of the size of the fine particles is limited. For example, JP-A-8-113773 abrades the surface of a silicon plate with zirconium oxide particles, which have a particle size of 7.0 μm.

JP-A-2000-204353 discloses an aqueous dispersion comprising a mixture of organic particles of silica, alumina or zirconia, and polymer particles. The specification of this patent application describes an average particle size of the inorganic particles in the range of 0.12 to 0.8 μm.

Hitherto, the zirconium oxide particles are not used as an abrasive material by themselves, but rather they are used in combination with other abrasive particles such as aluminum oxide particles, silicon oxide particles, etc. This may be because the conventional zirconium oxide particles do not have satisfactory properties such as a particle size or a particle shape as an abrasive.

(3) Aluminum Oxide

Aluminum oxide is widely used as an abrasive of an abrasive sheet, an abrasive liquid, etc., and various methods are known as the production method of aluminum oxide particles. In general, aluminum oxide, which is prepared by sintering, is milled with a ball mill, etc. to obtain fine particles. However, the aluminum oxide particles produced by such a method have a broad particle size distribution. In addition, since the particles are mechanically ground, the lower limit of the particle size is in a submicron order and it is difficult to further decrease the particle size.

Alternatively, aluminum oxide particles can be produced by precipitating aluminum hydroxide by a neutralization reaction and thermally treating precipitated aluminum hydroxide. However, this method can produce aluminum oxide particles having a small particle size, but the particle shapes are irregular so that the resulting particles do not have sufficient abrasion ability when used as an abrasive. Furthermore, secondary particles tend to be formed by agglomeration of particles. Thus, a large amount of energy and a long time are required to disperse the particles in a liquid medium particularly and obtain a homogeneous dispersion, when an abrasive liquid is prepared. For example, JP-A-7-315833 discloses that plate-form aluminum oxide, which is prepared by sintering, is finely milled with a non-metallic medium for a long time to break agglomeration. However, the fine particles have the lower limit of a particle size and the obtained aluminum oxide particles have inherently a broad particle size distribution, since this method produces fine particles by milling.

The production of plate-form aluminum oxide using a hydrothermal method has been known for a long time. For example, JP-B-37-7750 and JP-B-39-13465 describe the production of plate-form alumina. However, the particle size of plate-form alumina obtained is from several microns to several hundred microns, and such a method is unsatisfactory to obtain fine particles.

Additionally, it is known to hydrothermally treating aluminum hydroxide, the particle size of which has been adjusted in a submicron order, in water or an alkaline aqueous medium at a high temperature of 350° C. or higher to obtain plate-form aluminum oxide in the submicron order (see, for example, JP-A-5-17132 and JP-A-6-316413). This method uses the hydrothermal reaction which easily produces plate-form aluminum oxide having good crystallinity to transform aluminum hydroxide to aluminum oxide. Therefore, the reaction should be carried out at a high temperature and a special reactor, which can withstand a high pressure, should be used. Furthermore, since this method uses the hydrothermal reaction, it is suitable for the production of aluminum oxide particles having a large particle size in the submicron order, but may be less suitable for the production of aluminum oxide fine particles having a size of 100 nm or less.

The fine particles of aluminum oxide having a particle size of 100 nm or less, good crystallinity and a narrow particle size distribution has been sought for the provision of an abrasive for an abrasive sheet or liquid for finishing, but aluminum oxide particles satisfying such a requirement has not bee developed as explained above.

(4) Silicon Oxide

Silicon oxide is also wellknown as an abrasive for an abrasive sheet, an abrasive liquid, etc. For example, fumed silica and colloidal silica are general products which are commercially available from various producers. A huge number of patent applications relating to abrasive sheets or abrasive liquids comprising such silicon oxide particles have been filed.

For example, JP-A-8-336758 and JP-A-9-248771 relate to an abrasive sheet comprising colloidal silica particles having a size of several ten nanometers as an abrasive, and describe that such an abrasive sheet is particularly useful for polishing the edge face of an optical connector ferrule. JP-A-8-267356 describes that a silicon wafer is polished using colloidal silica of 10 to 100 nm as an abrasive. JP-A-7-221059 describes that a semiconductor wafer is polished with colloidal silica having a specific shape. Furthermore, JP-A-6-313164 describes that a colloidal silica slurry comprising colloidal silica of several ten nanometers as an abrasive is effective to abrade a metal surface.

As described above, it is well known that the silicon oxide particles are useful as an abrasive, and the above patent publications describe that a spherical particle shape or a particle shape as close as possible to a spherical shape are effective.

On the other hand, the kinds of materials to be abraded or polished has been increased year by year, and abrading specifications required for such an increased number of materials have been diversified. To satisfy such requirements for the various abrading specifications, in the case of silicon oxide, the composition and surface structure of an abrasive sheet or the composition of an abrasive slurry has been improved rather than the improvement of the particles. However, insofar as the silicon oxide particles having a spherical shape and a particle size of several ten namometers, the improvements have limits, and it is difficult to cope with the abrasion in special applications.

(5) Iron Oxide

The inventors developed a novel iron oxide having a plate shape and pores in the thickness direction of the plate-form particles. Such a novel iron oxide are disclosed in JP-A-61-266311 and JP-A-61-266313, in which plate-form goethite particles are heated, dehydrated and reduced to form porous plate-form magnetite particles and then the magnetite particles are modified with cobalt, and these patent applications propose the use of the obtained iron oxide particles in magnetic recording.

JP-B-3-21489 describes annular oxide powder produced from plate-form goethite particles, and proposes the use of such an oxide as electric materials (e.g. magnetic powder, etc.), pigments for reinforcing paints, reinforcing materials for composite materials, medical materials, and so on. In this JP-B publication, an aqueous solution of iron chloride is dropwise added to an aqueous solution containing sodium hydroxide and an alkylamine to precipitate iron hydroxide, which is aged, washed and subjected to pH adjustment, followed by the hydrothermal treatment, to obtain plate form plate-form goethite. When the plate-form goethite is heated and dehydrated to obtain magnetic powder particles such ashematite particles, magnetite particles, γ-iron oxide particles, etc., which have pores at their centers.

### DISCLOSURE OF THE INVENTION

One object of the present invention is to provide non-magnetic oxides having a specific particle size and a specific particle shape, such as the particles of cerium oxide, zirconium oxide, aluminum oxide, silicon oxide and iron oxide, which are useful as abrasive particles for abrasive sheets, abrasive liquids (slurry-form abrasives), etc., additives for coating type magnetic recording media, and also additives for functional optical films, as well as a method for producing such non-magnetic particles and the use thereof.

To achieve the above object, extensive studies have been made. As a result, a novel production method, which is entirely different from conventional production methods of non-magnetic oxide particles have been completed. Consequently, non-magnetic particles having a plate-form shape and a particle size of 10 to 100 nm, for example, cerium oxide particles, zirconium oxide particles, aluminum oxide particles, silicon oxide particles and iron oxide particles have been developed.

That is, the plate-form non-magnetic particles of the present invention is characterized in that the particle shape is plate-form and the particle size is 10 nm to 100 nm. Such non-magnetic particles include cerium oxide particles, zirconium oxide particles, aluminum oxide particles, silicon oxide particles and iron oxide particles having a plate-form shape and a particle size of 10 to 100 nm.

According to the present invention, the oxide particles cerium oxideparticles, zirconium oxide particles, aluminum oxide particles, silicon oxide particles and iron oxide particles having the specific particle shape and the specific particle size can be produced by adding an aqueous solution of a metal salt or a non-metal salt to an alkaline aqueous solution to obtain a hydroxide or hydrate of the metal or non-metal element, heating the hydroxide or hydrate at a temperature of 110 to 300° C. in the presence of water, filtrating and drying the product and then heating the product at a temperature of 300 to 1200° C. in an air.

Herein, the “metal salt or non-metal salt” or the “metal or non-metal element” are used since cerium, zirconium, aluminum and iron are metal elements while silicon may not be a metal element. That is, the “non-metal element” primarily means silicon, and the non-metal salt” primarily means a salt comprising silicon, or a silicon salt. Hereinafter, for simplicity, the “metal or non-metal element” will be referred to as “metal”, while the “metal salt or non-metal salt” will be referred to as “metal salt”,

Since the method of the present invention uses a high purity metal salt such as a chloride or anitrate of the metal, the product contains substantially no element which has adverse effects on the abrading properties of the product. In addition, chlorine atoms or nitric acid contained in the raw materials do not substantially remain in the finally obtained particles of cerium oxide, zirconium oxide, aluminum oxide, silicon oxide and iron oxide, since they are removed by dissipation with heating. Thus, quite high purity non-magnetic oxide particles can be obtained.

### BRIEF DESCRIPTION OF THE DRAWINGS

FIG. 1 is an X-ray diffraction spectrum of the cerium oxide particles obtained in Example 1.

FIG. 2 is a transmission electron microscopic photograph of the cerium oxide particles obtained in Example 1 (magnification: 200,000 times).

FIG. 3 is a transmission electron microscopic photograph of the cerium oxide particles obtained in Example 2 (magnification: 200,000 times).

FIG. 4 is a transmission electron microscopic photograph of the cerium oxide particles obtained in Example 3 (magnification: 200,000 times).

FIG. 5 is an X-ray diffraction spectrum of the zirconium oxide particles obtained in Example 8.

FIG. 6 is a transmission electron microscopic photograph of the zirconium oxide particles obtained in Example 8 (magnification: 200,000 times).

FIG. 7 is a transmission electron microscopic photograph of the zirconium oxide particles obtained in Example 9 (magnification: 200,000 times).

FIG. 8 is an X-ray diffraction spectrum of the aluminum oxide particles obtained in Example 15.

FIG. 9 is a transmission electron microscopic photograph of the aluminum oxide particles obtained in Example 15 (magnification: 200,000 times).

FIG. 10 is an X-ray diffraction spectrum of the aluminum oxide particles obtained in Example 16.

FIG. 11 is a transmission electron microscopic photograph of the aluminum oxide particles obtained in Example 17 (magnification: 200,000 times).

FIG. 12 is a transmission electron microscopic photograph of the aluminum oxide particles obtained in Example 18 (magnification: 200,000 times).

FIG. 13 is an X-ray diffraction spectrum of the aluminum oxide particles obtained in Example 20.

FIG. 14 is a transmission electron microscopic photograph of the aluminum oxide particles obtained in Example 20 (magnification: 200,000 times).

FIG. 15 is a transmission electron microscopic photograph of the silicon oxide particles obtained in Example 22 (magnification: 200,000 times).

FIG. 16 is a transmission electron microscopic photograph of the iron oxide particles obtained in Example 28 (magnification: 200,000 times).

FIG. 17 is a transmission electron microscopic photograph of the iron oxide particles obtained in Example 29 (magnification: 200,000 times)

### BEST EMBODIMENTS FOR CARRYING OUT THE INVENTION

According to the method of the present invention, in the first step, an aqueous solution of a salt of cerium, zirconium, aluminum, silicon or iron is added to an alkaline aqueous solution to form a hydroxide or hydrate of the metal, and the hydroxide or hydrate of the metal is heated at a temperature of 110 to 3000° C. in the presence of water. Thereby, the metal hydroxide or metal hydrate particles having the desired particle shape and the intended particle size are obtained. Then, in the second step, the hydroxide or hydrate of the metal is heated in the air to obtain the particles of cerium oxide, zirconium oxide, aluminum oxide, silicon oxide or iron oxide, which have a uniform particle size distribution and are rarely sintered or agglomerated.

In the above method, when the hydroxide or hydrate of the metal is optionally aged between the first and second steps, the particles have the more uniform particle size and better plate-form shape.

The present invention successfully developed the particles of cerium oxide, zirconium oxide, aluminum oxide, silicon oxide and iron oxide having a plate-form shape and a particle size of 10 to 100 nm, which cannot be produced by the conventional methods, based on the innovative idea that the step for adjusting the shape and size of the particles (the first step) and the step for deriving the inherent properties of the material to the maximum (the second step) are separately carried out.

Herein, the term “plate-form” means that a ratio of the maximum diameter to the thickness of the particle (plate ratio) exceeds 1. The plate ratio preferably exceeds 2 and is up to 100, more preferably from 3 to 50, particularly preferably from 5 to 30. When the plate ratio is 2 or less, some particles may project above the surface of the coated layer when the particles are used to produce the abrasive sheet so that such particles may damage a material to be abraded. When the plate ratio exceeds 100, the particles may be broken during abrading so that debris tend to damage the material to be abraded.

The particles of cerium oxide, zirconium oxide, aluminum oxide, silicon oxide or iron oxide, which are produced by the method described above, are characterized by that they rarely sintered or agglomerated together, have a narrow particle size distribution and a plate-form shape. Because of these characteristics, the non-magnetic oxide particles of the present invention have excellent properties, which can not be possessed by the conventional non-magnetic particles, when they are used as abrasive particles of the abrasive sheet or abrasive liquid, additives of various coating type magnetic recording media and also additives of various optical films.

When the particles of cerium oxide, zirconium oxide, aluminum oxide, silicon oxide or iron oxide according to the present invention are used as an abrasive or an additive, they are preferably crystalline. Although the conventional non-magnetic particles may have a spectrum specific to the non-magnetic oxide particles in an X-ray diffraction analysis or the like, they may not have a sufficient crystallinity, and thus, they are not always satisfactory when used as the abrasive or additive.

The cerium oxide particles can be used as an abrasive for chemical polishing. In such an application, the purity of cerium oxide is important, and high purity cerium oxide is required. However, the cerium oxide particles produced by the conventional method do not have a satisfactory purity. In contrast therewith, the cerium oxide particles of the present invention have the satisfactory purity. In this viewpoint, the cerium oxide particles of the present invention are suitable as an abrasive for chemical polishing.

The present inventors have studied particle shapes which exhibit good properties as abrasives. As a result, it has been found that the edges of the plate-form particles effectively contribute to the function as abrasive particles, when observed with an electron microscope.

Accordingly, the present invention firstly succeeded in the production of particles of cerium oxide, zirconium oxide, aluminum oxide, silicon oxide or iron oxide, which have the specific particle shape. The oxide particles produced according to the present invention are used as abrasive particles highly suitable for polishing semiconductors, optical fibers, lenses, etc. and also used in a wide variety of applications, for example, as particulate additives of coating type magnetic media, and further as particulate additives of functional optical films by making use of the specific particle shape.

The plate-form non-magnetic oxide particles of the present invention can be roughly classified into those having substantially no pores such as the particles of cerium oxide, zirconium oxide, aluminum oxide and silicon oxide, and those having pores such as the iron oxide particles. The former particles having substantially no pores are preferably used as additive particles of the coating type magnetic recording media or the functional optical films. In addition, the former particles are preferably used in fields in which the coloring should be avoided for example, in the functional films, since they are not colored. The “plate-form oxide particles having substantially no pores” mean that, when 300 particles are observed, the number of oxide particles having pores in the thickness direction of the plate is 10% or less.

In the method of the present invention, a compound comprising cerium, zirconium, aluminum, silicon or iron as a raw material is dissolved inwater, and then dropwise added to an alkaline aqueous solution to form the precipitate of the hydroxide or hydrate of the above metal element. The alkaline aqueous solution, which is used to form the precipitate, is not limited. A hydroxyalkylamine is preferably added to the alkaline aqueous solution, since the plate-form particles having a narrow particle size distribution are easily obtained, when the hydroxyalkylamine is added. The suspension containing the hydroxide or hydrate is hydrothermally treated, for example, in an autoclave. Prior to the hydrothermal treatment, the suspension may preferably aged, since the oxide particles having good crystallinity and a narrow particle size distribution can be easily obtained. After the hydrothermal treatment, the particles are washed with water, filtrated and then dried. The dried particles are further heated to obtain the particles of cerium oxide, zirconium oxide, aluminum oxide, silicon oxide or iron oxide.

The method for producing the non-magnetic plate-form particles (oxide particles) and the use of the non-magnetic plate-form particles produced by such a method will be explained in detail.

Preparation of Precipitate:

The chloride, nitrate or sulfate of cerium, zirconium, aluminum or iron, or sodium silicate is dissolved in water to form an aqueous solution containing metal ions (aqueous solution of metal salt). Separately, an alkaline aqueous solution is prepared. As an alkali, sodium hydroxide, potassium hydroxide, lithium hydroxide, or aqueous ammonia is preferably used. To the alkaline aqueous solution, an alkylamine, which is a crystal growth regulator, may be added, since particles having good plate-form shape can be obtained. Examples of the alkylamine include monoethanolamine, triethanolamine, isobutanolamine, propanolamine, etc. Among them, ethanolamine is particularly preferable since the particles having better plate-form shape can be obtained.

Next, the aqueous solution of the metal salt is dropwise added to the alkaline aqueous solution to form the precipitate of the metal hydroxide orhydrate. Preferably, pH of the suspension containing the precipitate is adjusted in a range of 8 to 11, and the suspension is aged at room temperature for about one day. The adjustment of pH and the aging of the suspension are effective to obtain the oxide particles having good plate-form shape and a narrow particle size distribution.

Hydrothermal Treatment:

The suspension containing the precipitated hydroxide or hydrate of the metal is hydrothermally treated in an autoclave, etc. In this hydrothermal treatment, the suspension is preferably washed with water to remove by-products or residual materials, and then the pH of the suspension is readjusted with sodium hydroxide, etc., although the suspension as such may be hydrothermally treated. After the readjustment, the pH of the suspension is preferably from 7 to 11. When the pH value in this step is lower than 7, the crystal of the material does not grow sufficiently in the hydrothermal treatment. When the pH value in this step exceeds 11, the particle size distribution may be broadened, or the particles having the small size as intended may hardly be obtained. The pH is more preferably from 7 to 10.

A temperature in the hydrothermal treatment is preferably from 110 to 300° C. When the temperature is less than 110° C., the hydroxide or hydrate of the metal having the specific shape may not be obtained. A temperature exceeding 300° C. has no advantage, since a pressure generated increases so that an expensive apparatus should be used.

The hydrothermal treatment time is preferably from 1 to 4 hours. When the hydrothermal treatment time is too short, the particles do not grow sufficiently to the specific shape. When the hydrothermal treatment time is too long, there is no drawback but the production costs increase.

Heating:

After the hydrothermal treatment, the hydroxide or hydrate of the metal is filtrated and dried, and then heated. Before filtration, the pH of the suspension is preferably adjusted in a neutral range around 6 to 9 by washing with water. When the pH is hither than this range, sodium, etc. may remain and cause sintering of the particles in the subsequent heat treatment, or interfere with the crystal growth of the particles.

In the case of cerium, zirconium, aluminum and iron, the hydroxide or hydrate of such a metal may be silicated by adding a silicon compound such as sodium silicate. The silication is effective for maintaining the finally obtained particles of cerium oxide, zirconium oxide, aluminum oxide or iron oxide in the specific shape.

After the filtration and drying, the hydroxide or hydrate of the metal is heated to obtain the oxide particles. The heating atmosphere is not limited, but the heating in an air is preferable, since the heating cost is lowest. The temperature in this heating step is preferably from 300 to 1500° C. When this temperature is lower than 300° C., oxide particles having a plate-form shape and also good crystallinity may not be obtained. When this temperature is higher than 1500° C., the particle size increases due to sintering, or the particle size distribution is broadened. By such a heating treatment, the particles of cerium oxide, zirconium oxide, aluminum oxide, iron oxide or silicon oxide are obtained. When the unreacted compounds are removed by washing with water and the like, the oxide particles having a higher purity can be obtained. Thus, the oxide particles are preferably washed with water in the final step, when they are used as an abrasive for chemical polishing and so on.

To obtain the oxide particles having both the plate-form shape and the good crystallinity, the above heating treatment is an effective method. However, in the case of cerium oxide and zirconium oxide, oxide particles having the fluorite structure, which is the inherent structure of these oxides, can be obtained without heating treatment. In such a case, the plate-form particles can be obtained without heating although depending on the conditions of aging and hydrothermal treatment. In the case of silicon oxide, the plate-form silicon oxide particles having a composition of SiO₂ can be produced without heating treatment. The plate-form particles, which are obtained without heating treatment, are usually fine particles having a particle size of 10 nm. Therefore, such fine particles are preferably used in the form of a slurry without drying.

The oxide particles obtained by the above process have a particle size of 10 nm to 100 nm, preferably 20 nm to 90 nm, which is preferable when they are used as an abrasive of a finish polishing sheet or an abrasive liquid. When the oxide particles are analyzed with X-ray diffraction, an X-ray diffraction spectrum has clear peaks corresponding to the crystal structure of CeO₂ or ZrO₂ having the fluorite structure in the case of cerium oxide or zirconium oxide. Furthermore, when the oxide particles are observed with an electronmicroscope, crystal boundaries are clearly seen. These data indicate that the oxide particles produced according to the present invention have the excellent crystallinity, which cannot be attained by the conventional methods.

In the case of aluminum oxide, the heating treatment can provide the plate-form particles with good crystallinity which have any crystal structure such as γ-Al₂O₃, δ-Al₂O₃, θ-Al₂O₃, α-Al_{2O}₃, etc. For example, alumina having a single crystal structure of γ-alumina, δ-alumina, θ-alumina or α-alumina, or a mixture of two or more types of alumina having different crystal structures can be prepared by adding an aqueous solution of an aluminum salt to an alkaline aqueous solution to form the hydroxide or hydrate of aluminum, heating the hydroxide or hydrate of aluminum at a temperature of 110 to 300° C. in the presence of water, filtering and drying the particles to obtain boehmite particles, heating the boehmite particles in an air at a temperature of 300 to 1200° C. or 400 to 1500° C., and optionally washing the produced particles to remove products other than aluminum oxides or residual materials.

In the case of silicon oxide, clear diffraction peaks showing crystals may not be found in an X-ray diffraction spectrum. However, it is confirmed that the silicon oxide particles substantially have the composition of SiO₂ by a fluorescent X-ray analysis.

Use of Non-Magnetic Plate-Form Particles:

The non-magnetic particles, i.e. the oxide particles (e.g. cerium oxide particles, zirconium oxide particles, aluminum oxide particles, silicon oxide particles and iron oxide particles), which are produced by the method described above, have the specific shape and the specific particle size. Therefore, when they are used as an abrasive of an abrasive member or an abrasive liquid, they exhibit excellent abrading or polishing properties without damaging materials to be abraded, which cannot be achieved by the conventional particulate abrasive. That is, when the conventional particulate abrasive is used, it is difficult to form a smoothly abraded or polished surface of a material without damage while maintaining the abrading properties. However, when the oxide particles of the present invention are used, it is possible to abrade the surface of a material without damaging the surface by making use of flat surfaces of the plates while abrading the material surface with the edges of the plate-form particles. The abrasive member includes a variety of items having various forms such as a sheet (abrasive sheet), a tape (abrasive tape), a disc (abrasive disc), a card, a rod, or any other solid forms.

In addition, according to the present invention, the non-magnetic plate-form particles include oxide particles in which pores are easily formed in the thickness direction of a plate such as iron oxide particles. Such pores are formed since the plate-form particles of the hydroxide are dehydrated in the heating treatment. The oxide particles having pores do not lose the characteristics of the oxide particles of the present invention such as abrading properties. When a part of the iron elements are substituted with other metal element such as aluminum, zirconium, etc., the hardness of the iron oxide particles can be controlled so that the abrading properties are adjusted according to the application of the abrasive.

An abrasive liquid, that is, a slurry-form abrasive, can be prepared by dispersing the non-magnetic plate-form particles of the present invention in a liquid medium preferably in the presence of a dispersant. The abrasive particles, that is, the cerium oxide particles, zirconium oxide particles, aluminum oxide particles, silicon oxide particles and iron oxide particles have different hardness. Thus, when two or more kinds of the oxide particles are used in combination, the hardness of the abrasive can be precisely adjusted, so that the abrasive liquids suitable for a wide variety of applications can be prepared. In particular, when the general purpose colloidal silica and the abrasive particles according to the present invention are used together, the additional abrading properties can be imparted to the abrasive liquid in addition to the less satisfactory abrading properties of the colloidal silica. Therefore, the abrasive liquid can be used in a wider variety of applications. When such a mixture is used, the abrasive liquid has very good stability since the abrasive particles are no sintered or agglomerated together and have a uniform particle size distribution so that the different particles are not separated in the liquid.

The non-magnetic plate-form particles of the present invention are very useful as additive particles of coating type magnetic recording media. In this case, the plate-form particles having no pore are preferable, since the acicular particles of a magnetic powder are trapped in the pores of the non-magnetic particles so that the orientation of the magnetic powder may be disturbed, and furthermore, the thickness of a magnetic layer may fluctuate.

The magnetic layer of coating type magnetic recording media is made thinner and thinner because of the requirement for high density recording. Hitherto, particulate aluminum oxide, silicon oxide and iron oxide have been used as additives of the coating type magnetic recording media. When the thickness of the magnetic layer is decreased, such particulate additives protrude from the surface of the magnetic layer so that the surface smoothness of the magnetic layer is deteriorated and the noise is increased. When the plate-form particles of the present invention are used, the planes of the plate-form particles can be aligned in parallel with the plane of the magnetic layer. Therefore, the magnetic recording media comprising a magnetic layer with a smooth surface can be produced while maintaining the cleaning function of the additive particles.

Furthermore, the oxide particles of the present invention have good light transmission based on the optical properties inherent to the oxide materials and also the plate-form shape, when they are used as additives of various functional films such as optical films. That is, when the planes of the plate-form particles are aligned in parallel with the plane of the functional film, the transparent functional film having good light transmittance while exhibiting the interaction with light, which is inherent to the materials, can be obtained. Accordingly, a large variety of films, for example, an anti-reflection film having a plurality of coatings comprising oxide particles of the present invention which have different refractive indices, and a film having a high refractive index and good light transmittance can be provided. Thus, the oxide particles of the present invention can find a large number of applications.

It is possible to form a coating film having a very small mechanical or thermal deformation rate in a specific direction using the isotropy in the plate of the particle due to the plate-form. In this case, the colorless plate-form particles such as the particles of aluminum oxide, zirconium oxide, cerium oxide and silicon oxide are preferably used, since the coating film is not colored. When the particles have pores, they may cause the fluctuation of a refractive index or the decrease of the transparency. Thus, the particles having no pore are preferable.

As explained above, the oxide particles of the present invention have the plate-form shape and an average particle size of 10 nm to 100 nm, and also they have a very good particle size distribution. When such particles are used, the properties of products comprising the oxide particles are significantly improved in comparison with those comprising the conventional oxide particles, and the oxide particles can exploit novel applications which cannot be exploited by the conventional oxide particles.

### EXAMPLES

Hereinafter, the Examples of the present invention will be illustrated together with the Comparative Examples.

### (1) Examples of Cerium Oxide Particles

### Example 1

An alkaline aqueous solution was prepared by dissolving sodium hydroxide (0.75 mol) and 2-aminoethanol (100 ml) in water (800 ml). Separately, an aqueous cerium chloride solution was prepared by dissolving cerium chloride (III) heptahydrate (0.074 mol) in water (400 ml). To the alkaline aqueous solution was added dropwise the aqueous cerium chloride solution to form a precipitate containing cerium hydroxide at about 25° C. The pH of the suspension was 10.8. The precipitate in the form of a suspension was aged for 20 hours and washed with water until the pH of the suspension reached 7.9.

Next, the supernatant was removed, and the suspension of the precipitate was charged in an autoclave and subjected to hydrothermal reaction at 200° C. for 2 hours.

The resultant product was filtered and dried at 90° C. in an air. The resultant solid was lightly crushed in a mortar and heated in an air at 600° C. for one hour to obtain cerium oxide particles. After the heating treatment, the cerium oxide particles were washed with water using an ultrasonic disperser, and filtered and dried so as to remove the unreacted substances and the residue.

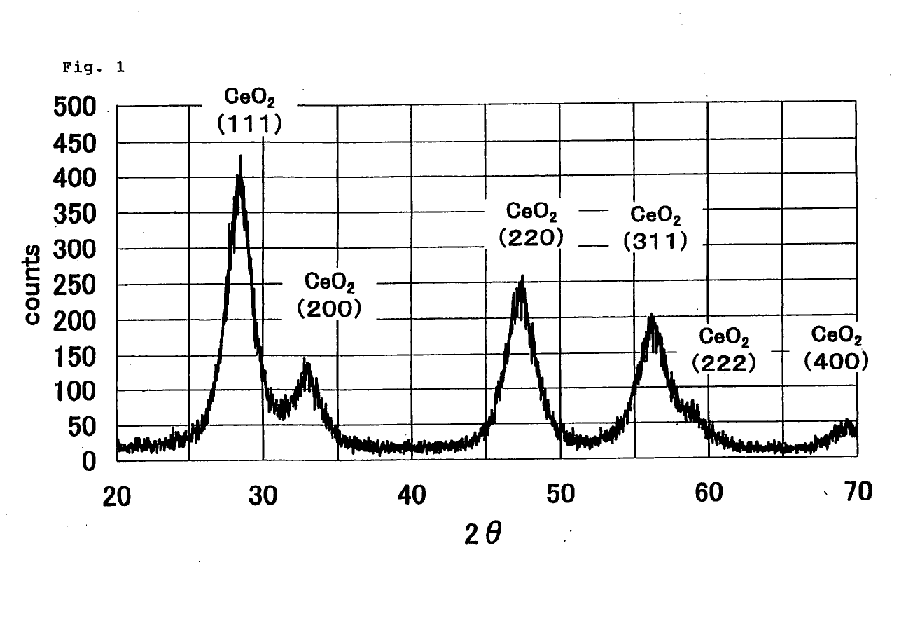

The resultant cerium oxide particles were subjected to X-ray diffractometry, and a spectrum corresponding to cerium oxide with a fluorite structure was clearly observed (see FIG. 1). The crystallite size was calculated from the width of a peak corresponding to the plane (111) of cerium oxide according to the Scherre method. As a result, the crystallite size was 12.7 nm. Further, the shapes of the cerium oxide particles were observed with a transmission electron microscope, and were found to be hexagonal plate-form particles with a particle size of 10 to 20 nm.

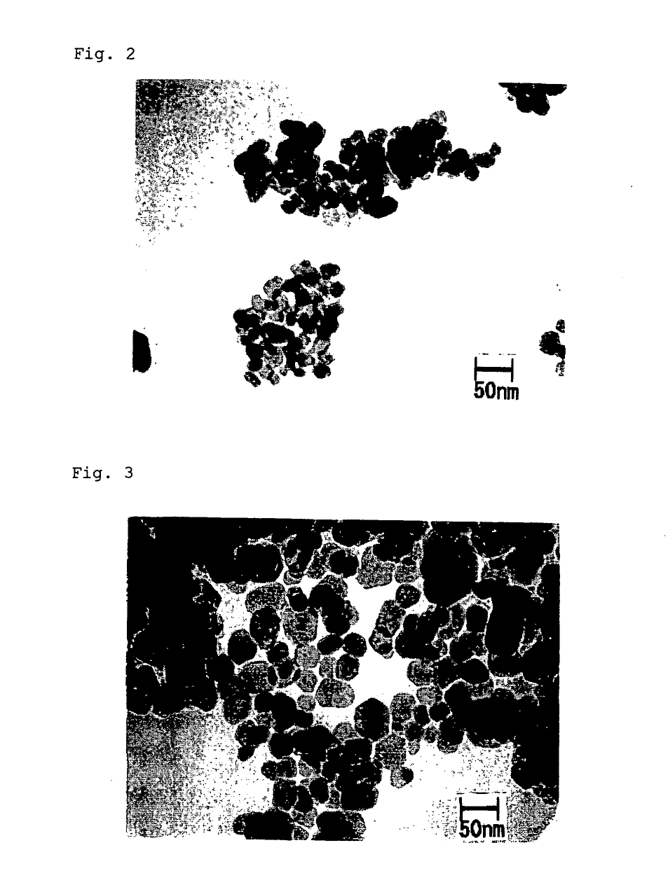

FIG. 1 shows the X-ray diffraction spectrum of the cerium oxide particles, and FIG. 2 shows the transmission electron microphotograph (magnification: 200,000 times). The synthesis conditions for the cerium oxide particles, the crystal structure found by the X-ray diffraction, the average particle sizes and the shapes of the particles found based on the transmission electron microphotograph, and the crystallite size calculated from the X-ray diffraction peak width are summarized in Table 1.

### Example 2

Cerium oxide particles were prepared by forming a precipitate containing cerium hydroxide, washing it with water, filtering, drying and subjecting it to heating treatment in the same manner as in the synthesis of the cerium oxide particles of Example 1, except that the heating temperature of the product of hydrothermal treatment was changed from 600° C. to 800° C.

The X-ray diffraction spectrum of the resultant cerium oxide particles were measured, and a spectrum corresponding to cerium oxide with a fluorite structure was observed as in Example 1. The crystallite size calculated from the width of a peak corresponding to the plane (111) according to the Scherre method was 17.2 nm. Further, the shapes of the cerium oxide particles were observed with a transmission electron microscope and found to be hexagonal particles with a particle size of 10 to 25 nm.

FIG. 3 shows the transmission electron microphotograph of the cerium oxide particles (magnification: 200,000 times). The synthesis conditions, the crystal structure observed by X-ray diffraction, the average particle sizes and the shapes of the particles found based on the transmission electron microphotograph, and the crystallite size calculated from the X-ray diffraction peak width are summarized in Table 1.

### Example 3

Cerium oxide particles were prepared by forming a precipitate containing cerium hydroxide, washing it with water, filtering, drying and subjecting it to heating treatment in the same manner as in the synthesis of the cerium oxide particles of Example 1, except that the heating temperature of the product of hydrothermal treatment was changed from 600° C. to 1,000° C.

The X-ray diffraction spectrum of the resultant cerium oxide particles was measured, and a spectrum corresponding to cerium oxide with a fluorite structure were observed as in Example 1. The crystallite size calculated from the width of a peak corresponding to the plane (111) according to the Scherre method was 32.4 nm. Further, the shapes of the cerium oxide particles were observed with a transmission electron microscope and found to be hexagonal or rectangle plate-form particles with a particle size of 50 to 100 nm.

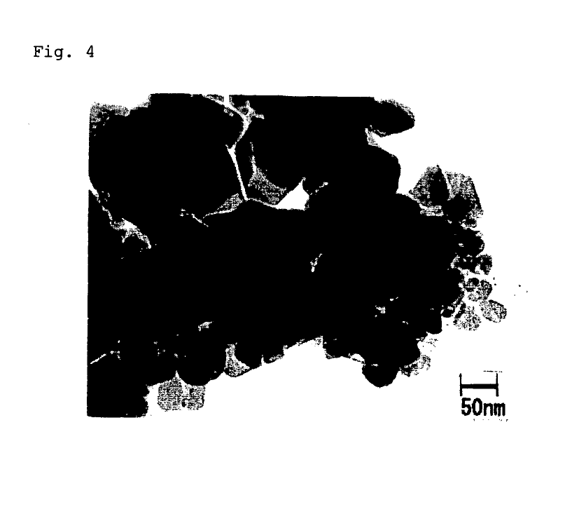

FIG. 4 shows the transmission electron microphotograph of the cerium oxide particles (magnification: 200,000 times) The synthesis conditions, the crystal structure observed by X-ray diffraction, the average particle sizes and the shapes of the particles found based on the transmission electron microphotograph, and the crystallite size calculated from the X-ray diffraction peak width are summarized in Table 1.

### Example 4

In the synthesis of the cerium oxide particles of Example 1, the precipitate was subjected to hydrothermal treatment and then, washed with water in an amount 500 times larger than the volume of the suspension, filtered and dried. The pH of the washed precipitate was 7.5. The steps following the heating treatment were carried out in the same manner as in Example 1 to obtain cerium oxide particles.

The X-ray diffraction spectrum of the resultant cerium oxide particles was measured, and a spectrum corresponding to cerium oxide with a fluorite structure was observed. The crystallite size calculated from the width of a peak corresponding to the plane (111) according to the Scherre method was 11.5 nm. Further, the shapes of the cerium oxide particles were observed with a transmission electron microscope and found to be hexagonal plate-form particles with a particle size of 10 to 15 nm.

The synthesis conditions, the crystal structure observed by X-ray diffraction, the average particle sizes and the shapes of the particles found based on the transmission electron microphotograph, and the crystallite size calculated from the X-ray diffraction peak width are summarized in Table 1.

### Example 5

Cerium oxide particles were prepared by forming a precipitate containing cerium hydroxide, washing with water, filtering, drying and subjecting the same to heating treatment in the same manner as in the synthesis of the cerium oxide particles of Example 1, except that an aqueous 4N sodium silicate solution (0.04 g) and then an aqueous 0.8N hydrochloric acid solution were further added to the product of the hydrothermal treatment, so as to adjust the pH to 7.4.

The X-ray diffraction spectrum of the resultant ceriumoxide particles was measured, and a spectrum corresponding to cerium oxide with a fluorite structure was observed. The crystallite size calculated from the width of a peak corresponding to the plane (111) according to the Scherre method was 10.6 nm. Further, the shapes of the cerium oxide particles were observed with a transmission electron microscope and found to be hexagonal plate-form particles with a particle size of 10 to 15 nm.

The synthesis conditions, the crystal structure observed by X-ray diffraction, the average particle sizes and the shapes of the particles found based on the transmission electron microphotograph, and the crystallite size calculated from the X-ray diffraction peak width are summarized in Table 1.

### Example 6

Cerium oxide particles were prepared in the same manner as in the synthesis of the cerium oxide particles of Example 1, except that after the product was subjected to heating treatment at 600° C. in an air, it was washed with water by using an ultrasonic disperser.

The X-ray diffraction spectrum of the resultant cerium oxide particles was measured, and a spectrum corresponding to cerium oxide with a fluorite structure was observed. The crystallite size calculated from the width of a peak corresponding to the plane (111) according to the Scherre method was 12.3 nm. Further, the shapes of the cerium oxide particles were observed with a transmission electron microscope and found to be hexagonal plate-form particles with a particle size of 10 to 20 nm.

The synthesis conditions, the crystal structure observed by X-ray diffraction, the average particle sizes and the shapes of the particles found based on the transmission electron microphotograph, and the crystallite size calculated from the X-ray diffraction peak width are summarized in Table 1.

### Example 7

Cerium oxide particles were prepared in the same manner as in the synthesis of the cerium oxide particles of Example 1, except that the amount of sodium hydroxide added was changed to 0.90 mol from 0.75 mol, and that no 2-aminoethanol was added. The pH of the precipitate was 10.5. Then, the suspension of the precipitate was aged, subjected to hydrothermal treatment, washed with water, filtered, dried and further subjected to a heating treatment to obtain the cerium oxide particles.

The X-ray diffraction spectrum of the resultant cerium oxide particles was measured, and a spectrum corresponding to cerium oxide with a fluorite structure was observed. The crystallite size calculated from the width of a peak corresponding to the plane (111) according to the Scherre method was 20.1 nm. Further, the shapes of the cerium oxide particles were observed with a transmission electron microscope and found to be hexagonal plate-form particles with a particle size of 20 to 30 nm, although the particle size distribution was slightly wider.

The synthesis conditions, the crystal structure observed by X-ray diffraction, the average particle sizes and the shapes of the particles found based on the transmission electron microphotograph, and the crystallite size calculated from the X-ray diffraction peak width are summarized in Table 1.

### Comparative Example 1

Cerium oxide particles were prepared in the same manner as in the synthesis of the cerium oxide particles of Example 1, except that the hydrothermal treatment of the precipitate containing cerium hydroxide was not done. The precipitate containing cerium hydroxide was directly washed with water, filtered, dried and subjected to a heating treatment to obtain the cerium oxide particles.

The X-ray diffraction spectrum of the resultant ceriumoxide particles was measured. While a spectrum corresponding to cerium oxide with a fluorite structure was observed, the crystallite size was too large to be calculated from the width of a peak corresponding to the plane (111). Further, the shapes of the cerium oxide particles were observed with a transmission electron microscope and found to be sinteredorbe coarse and large particles with a particle size of 1 to 10 μm in a very wide particle size distribution.

The synthesis conditions, the crystal structure observed by X-ray diffraction, the average particle sizes and the shapes of the particles found based on the transmission electron microphotograph, and the crystallite size calculated from the X-ray diffraction peak width are summarized in Table 1.

(X-ray Diffraction Spectrum of Cerium Oxide Particles)

FIG. 1 is a graph of the X-ray diffraction spectrum of the cerium oxide particles prepared in Example 1, showing peaks corresponding to the crystal structure of the cerium oxide with the fluorite structure. Since similar results were obtained from all the particles of Examples and Comparative Examples, it can be confirmed that all the particles prepared in Examples and Comparative Examples were cerium oxide particles.

(Results of Observation of Cerium Oxide Particles with a Transmission Electron Microscope)

FIGS. 2 to 4 are the transmission electron microphotographs of the cerium oxide particles prepared in Examples 1 to 3, respectively. In Examples 1 to 3, the temperatures for the heating treatments after the hydrothermal treatments are 600° C., 800° C. and 10,000° C., respectively. It is seen that, with an increase in the temperature for the heating treatment, the average particle size tends to increase from about 10 nm to about 100 nm. This fact proves that the crystals of the cerium oxide particles are growing in the course of the heating treatment.

The synthesis conditions for the cerium oxide particles of Examples and Comparative Examples, the crystal structures thereof examined based on the X-ray diffraction, and the average particle sizes and shapes thereof evaluated from the transmission electron microphotographs are summarized in Table 1. Each of the particle sizes evaluated from the above photographs was determined from the average particle size of 300 particles.

TABLE 1

| | | | Temp. | | | | | | |
|---|---|---|---|---|---|---|---|---|---|
| | | | (° C.)/ | Temp. | | | | | |
| | | | time (hr.) | (° C.)/ | | | | | |
| | Crystal | PH in | of hydro- | time (hr.) | | Average | | | |
| | growth-controlling | precipitating | thermal | of heating | Crystal | particle | | Shape of | Crystallite |
| | agent | step | treatment | treatment | structure | size (nm) | | particle | size (nm) |
| Ex. 1 | 2-amino-ethanol | 10.8 | 200/2 | 600/1 | fluorite | 14 | | hexagonal | 13 |
| | | | | | structure | | | plate | |
| Ex. 2 | 2-amino-ethanol | 10.8 | 200/2 | 800/1 | fluorite | 18 | | hexagonal | 17 |
| | | | | | structure | | | plate | |
| Ex. 3 | 2-amino-ethanol | 10.8 | 200/2 | 1,000/1 | fluorite | 55 | | hexagonal-rectangle | 32 |
| | | | | | structure | | | plate | |
| Ex. 4 | 2-amino-ethanol | 10.8 | 200/2 | 600/1 | fluorite | 13 | | hexagonal | 12 |
| | | | | | structure | | | plate | |
| Ex. 5 | 2-amino-ethanol & | 10.8 | 200/2 | 600/1 | fluorite | 12 | | hexagonal | 11 |
| | sodium silicate | | | | structure | | | plate | |
| Ex. 6 | 2-amino-ethanol | 10.8 | 200/2 | 600/1 | fluorite | 14 | | hexagonal | 12 |
| | | | | | structure | | | plate | |
| Ex. 7 | None | 10.5 | 200/2 | 600/1 | fluorite | 24 | | hexagonal | 20 |
| | | | | | structure | | | plate | |
| Com. Ex. 1 | 2-amino-ethanol | 10.8 | no | 600/1 | fluorite | 3 | μm | agglomerated | >1,000 |
| | | | treatment | | structure | | | | |

As is apparent from Table 1, all the cerium oxide particles obtained in the above Examples are plate-form shaped, having a fluorite structure inherent to cerium oxide, and the particle sizes thereof are within the range optimal for use not only in abrasive members such as abrasive sheets and abrasive liquids but also in magnetic tapes and a variety of optical films which are formed by making good use of the plate-form shapes of the particles. On the other hand, the cerium oxide particles obtained in Comparative Example 1 have very large particle sizes, although having the fluorite structure, and also have a very wide particle size distribution and thus are not suitable for use in abrasive members and the like.

As is understood from the foregoing description, the cerium oxide particles of the present invention satisfy the conditions of plate-form shaped particles and a very small particle size of 100 nm or less. Therefore, it becomes possible to use the cerium oxide particles of the present invention for quite new applications which have been believed to be impossible to realize.

### (2) Examples of Zirconium Oxide Particles

### Example 8

An alkaline aqueous solution was prepared by dissolving sodium hydroxide (0.75 mol) and 2-aminoethanol (100 ml) in water (800 ml). Separately, an aqueous zirconium chloride solution was prepared by dissolving zirconium chloride (IV) (0.074 mol) in water (400 ml). To the alkaline aqueous solution was added dropwise the aqueous zirconium chloride solution to form a precipitate containing zirconium hydroxide at about 25° C. The pH of the suspension was 10.8. The precipitate in the state of a suspension was aged for 20 hours and then washed with water until the pH reached 7.8.

Next, the supernatant was removed, and the suspension of the precipitate was charged in an autoclave and subjected to a hydrothermal treatment at 20° C. for 2 hours.

The resultant product was filtered, dried, lightly crushed in a mortar, and subjected to a heating treatment at 600° C. in an air for one hour to obtain zirconium oxide particles. After the heating treatment, the zirconium oxide particles were further washed with water using an ultrasonic disperser, filtered and dried so as to remove the unreacted substances and the residue.

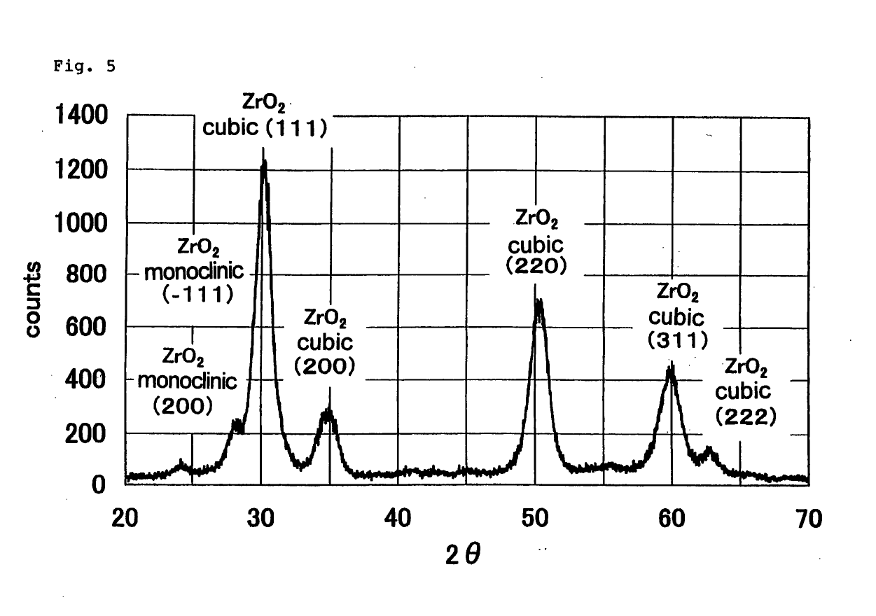

As a result of the measurement of the X-ray diffraction spectrum of the resultant zirconium oxide particles, a spectrum corresponding to zirconium oxide with a fluorite structure was clearly observed. The shapes of the zirconium oxide particles were observed with a transmission electron microscope. As a result, they are hexagonal plate-form particles with a particle size of 10 to 20 nm. FIG. 5 shows the X-ray diffraction spectrum of the zirconium oxide particles, and FIG. 6 shows the transmission electron microphotograph of the particles (magnification: 200,000 times). The synthesis conditions for preparing the zirconium oxide particles, the crystal structure of the particles examined by X-ray diffraction, and the average particle size and the shape of the particles found from the transmission electron microphotograph of the particles are summarized in Table 2.

### Example 92

Zirconium oxide particles were obtained by forming a precipitate containing zirconium hydroxide, washing the precipitate with water, filtering and drying the product and subjecting the product to a heating treatment in the same manner as in the synthesis of the zirconium oxide particles of Example 8, except that the temperature for the heating treatment of the product of the hydrothermal treatment was changed from 600° C. to 800° C.

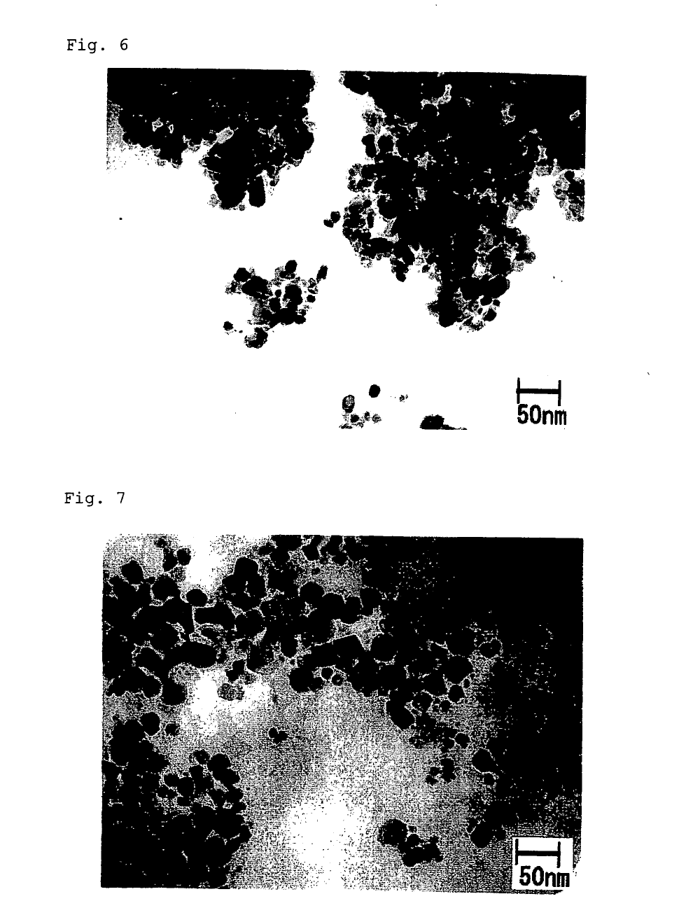

As a result of the measurement of the X-ray diffraction spectrum of the resultant zirconium oxide particles, a spectrum corresponding to zirconium oxide with a fluorite structure was clearly observed, as well as Example 8. The shapes of the zirconium oxide particles were further observed with a transmission electron microscope. As a result, they are hexagonal plate-form particles with a particle size of 20 to 30 nm. FIG. 7 shows the transmission electron microphotograph of the particles (magnification: 200,000 times) The synthesis conditions, the crystal structure of the particles examined by X-ray diffraction, and the average particle size and the shape of the particles found from the transmission electron microphotograph of the particles are summarized in Table 2.

### Example 10

Zirconium oxide particles were obtained by forming a precipitate containing zirconium hydroxide, washing the precipitate with water, filtering and drying the product and subjecting the product to a heating treatment in the same manner as in the synthesis of the zirconium oxide particles of Example 8, except that the temperature for the heating treatment of the product of the hydrothermal treatment was changed from 600° C. to 1,000° C.

As a result of the measurement of the X-ray diffraction spectrum of the resultant zirconium oxide particles, a spectrum corresponding to zirconium oxide with a fluorite structure was clearly observed, as well as Example 8. The shapes of the zirconium oxide particles were further observed with a transmission electron microscope. As a result, they are hexagonal plate-form particles with a particle size of 50 to 100 nm. The synthesis conditions, the crystal structure of the particles examined by X-ray diffraction, and the average particle size and the shape of the particles found from the transmission electron microphotograph of the particles are summarized in Table 2.

### Example 11

Zirconium oxide particles were obtained in the same manner as in Example 8, except that the product of the hydrothermal treatment was washed with water in an amount 500 times larger than the volume of the suspension of the precipitate, filtered and dried, and that the pH after the washing was 7.5, provided that the following steps after the heating treatment were carried out in the same manner as in Example 8.

As a result of the measurement of the X-ray diffraction spectrum of the resultant zirconium oxide particles, a spectrum corresponding to zirconium oxide with a fluorite structure was observed. The shapes of the zirconium oxide particles were further observed with a transmission electron microscope. As a result, they are hexagonal plate-form particles with a particle size of 10 to 15 nm. The synthesis conditions, the crystal structure of the particles examined by X-ray diffraction, and the average particle size and the shape of the particles found from the transmission electron microphotograph of the particles are summarized in Table 2.

### Example 12

Zirconium oxide particles were obtained by forming a precipitate containing zirconium hydroxide, washing the precipitate with water, filtering and drying the product and subjecting the product to a heating treatment in the same manner as in the synthesis of the zirconium oxide particles of Example 8, except that an aqueous 4N sodium silicate solution (0.04 g) and an aqueous 0.8N hydrochloric acid solution were further added to the product of the hydrothermal treatment so as to adjust the pH to 7.4.

As a result of the measurement of the X-ray diffraction spectrum of the resultant zirconium oxide particles, a spectrum corresponding to zirconium oxide with a fluorite structure was observed. The shapes of the zirconium oxide particles were further observed with a transmission electron microscope. As a result, they are hexagonal plate-form particles with a particle size of 10 to 15 nm. The synthesis conditions, the crystal structure of the particles examined by X-ray diffraction, and the average particle size and the shape of the particles found from the transmission electron microphotograph of the particles are summarized in Table 2.

### Example 13

Zirconium oxide particles were obtained in the same manner as in the synthesis of the zirconium oxide particles of Example 8, except that after the product was subjected to a heating treatment at 600° C. in an air, it was further washed with water using an ultrasonic disperser.

As a result of the measurement of the X-ray diffraction spectrum of the resultant zirconium oxide particles, a spectrum corresponding to zirconium oxide with a fluorite structure was observed. The shapes of the zirconium oxide particles were further observed with a transmission electron microscope. As a result, they are hexagonal plate-form particles with a particle size of 10 to 20 nm. The synthesis conditions, the crystal structure of the particles examined by X-ray diffraction, and the average particle size and the shape of the particles found from the transmission electron microphotograph of the particles are summarized in Table 2.

### Example 14

Zirconium oxide particles were obtained as follows:

A precipitate was formed in the same manner as in the synthesis of the zirconium oxide particles of Example 8, except that the amount of sodium hydroxide added was changed from 0.75 mol to 0.90 mol, and that no 2-aminoethanol was added. The suspension of the precipitate was aged, and then subjected to a hydrothermal treatment, washed with water, filtered and dried. The resulting product was further subjected to a heating treatment to obtain the zirconium oxide particles.

As a result of the measurement of the X-ray diffraction spectrum of the resultant zirconium oxide particles, a spectrum corresponding to zirconium oxide with a fluorite structure was clearly observed. The shapes of the zirconium oxide particles were further observed with a transmission electron microscope. As a result, they were found to be hexagonal plate-form particles with a particle size of 15 to 25 nm, although having a slightly wide particle size distribution. The synthesis conditions, the crystal structure of the particles examined by X-ray diffraction, and the average particle size and the shape of the particles found from the transmission electron microphotograph of the particles are summarized in Table 2.

### Comparative Example 2

Zirconium oxide particles were obtained as follows:

A precipitate containing zirconium hydroxide was formed and was directly washed with water, filtered and dried without undergoing a hydrothermal treatment, and then was subjected to a heating treatment in the same manner as in Example 8, to obtain the zirconium oxide particles.

As a result of the measurement of the X-ray diffraction spectrum of the resultant zirconium oxide particles, a spectrum corresponding to zirconium oxide with a fluorite structure was observed. The shapes of the zirconium oxide particles were observed with a transmission electron microscope. As a result, they were found to be sintered or be coarse particles which had a very wide particle size distribution of 1 to 10 μm, including very fine particles and coarse particles formed due to sintering or agglomeration. The synthesis conditions for preparing the zirconium oxide particles, the crystal structure of the particles examined by X-ray diffraction, and the average particle size and the shape of the particles found from the transmission electron microphotograph of the particles are summarized in Table 2.

(X-ray Diffraction Spectrum of Zirconium Oxide Particles)

FIG. 5 shows the X-ray diffraction spectrum of the zirconium oxide particles obtained in Example 8, indicating peaks which correspond to the crystal structure of zirconium oxide. Since similar effects could be obtained from all the particles of Examples, it is seen that all the particles of Examples were zirconium oxide particles.

(Results of Observation of Zirconium Oxide Particles with a Transmission Electron Microscope)

FIGS. 6 and 7 are the transmission electron microphotographs of the zirconium oxide particles obtained in Examples 8 and 9, respectively. The plate-form zirconium oxide particles were clearly observed from the photographs. In this regard, the average particle size evaluated from the photograph was determined from the average particle size of 300particles in the photograph.

TABLE 2

| | | | Temp. (° C.)/ | | | | |
|---|---|---|---|---|---|---|---|
| | | | time (hr.) | Temp. (° C.)/ | | | |
| | Crystal | PH in | of | time (hr.) | | | Av. |
| | growth-controlling | precipitating | hydro-thermal | of heating | Crystal | | particle |
| | agent | step | treatment | treatment | structure | Shape of particle | size (nm) |
| Ex. 8 | 2-amino-ethanol | 10.8 | 200/2 | 600/1 | fluorite | hexagonal plate | 19 |
| | | | | | structure | | |
| Ex. 9 | 2-amino-ethanol | 10.8 | 200/2 | 800/1 | fluorite | hexagonal plate | 25 |
| | | | | | structure | | |
| Ex. 10 | 2-amino-ethanol | 10.8 | 200/2 | 1,000/1 | fluorite | hexagonal plate | 70 |
| | | | | | structure | | |
| Ex. 11 | 2-amino-ethanol | 10.8 | 200/2 | 600/1 | fluorite | hexagonal plate | 13 |
| | | | | | structure | | |
| Ex. 12 | 2-amino-ethanol & | 10.8 | 200/2 | 600/1 | fluorite | hexagonal plate | 12 |
| | sodium silicate | | | | structure | | |
| Ex. 13 | 2-amino-ethanol | 10.8 | 200/2 | 600/1 | fluorite | hexagonal plate | 15 |
| | | | | | structure | | |
| Ex. 14 | None | 10.9 | 200/2 | 600/1 | fluorite | hexagonal plate | 20 |
| | | | | | structure | | |
| Com. Ex. 2 | 2-amino-ethanol | 10.8 | no | 600/1 | fluorite | agglomerated | >1,000 |
| | | | treatment | | structure | | |

As is apparent from Table 2, all the zirconium oxide particles obtained in the above Examples are plate-form shaped, having high crystallinity, and the particle sizes thereof were within the ranges optimal for use not only in abrasive members such as abrasive sheets and abrasive liquids but also in magnetic tapes and a variety of optical films which are formed by making good use of the shapes of the plate particles. On the other hand, the zirconium oxide particles obtained in Comparative Example 2 have very large particle sizes and have a very wide particle size distribution and thus are not suitable for use in abrasive members and the like.

As is understood from the foregoing description, the zirconium oxide particles of the present invention satisfy the conditions of plate-form shaped particles and a very small particle size of 100 nm or less. Therefore, it becomes possible to use the zirconium oxide particles of the present invention for quite new applications which have been believed to be impossible to realize.

### (3) Examples of Aluminum Oxide Particles

### Example 15

An alkaline aqueous solution was prepared by dissolving sodium hydroxide (0.75 mol) and 2-aminoethanol (100 ml) in water (800 ml). Separately, an aqueous aluminum chloride solution was prepared by dissolving aluminum chloride (III) heptahydrate (0.074 mol) in water (400 ml). To the alkaline aqueous solution was added dropwise the aqueous aluminum chloride solution to form a precipitate containing aluminum hydroxide at about 25° C. Then, hydrochloric acid was added dropwise to the precipitate to adjust the pH of the suspension to 10.2. The precipitate in the state of a suspension was aged for 20 hours and then washed with water in an amount about 1,000 times larger than the volume of the suspension.

Next, the supernatant was removed, and the pH of the suspension of the precipitate was adjusted to 10.0 by using an aqueous sodium hydroxide solution. The precipitate was charged in an autoclave and subjected to a hydrothermal treatment at 200° C. for 2 hours.

The resultant product was filtered, dried at 90° C. in an air, lightly crushed in a mortar, and subjected to a heating treatment at 600° C. in an air for one hour to obtain aluminum oxide particles. After the heating treatment, the aluminum oxide particles were washed with water using an ultrasonic disperser, filtered and dried so as to remove the unreacted substances and the residue.

As a result of the measurement of the X-ray diffraction spectrum of the resultant aluminum oxide particles, a spectrum corresponding to y-alumina was observed. The shapes of the aluminum oxide particles were observed with a transmission electron microscope. As a result, they were found to be rectangle plate-form particles with a particle size of 30 to 50 nm.

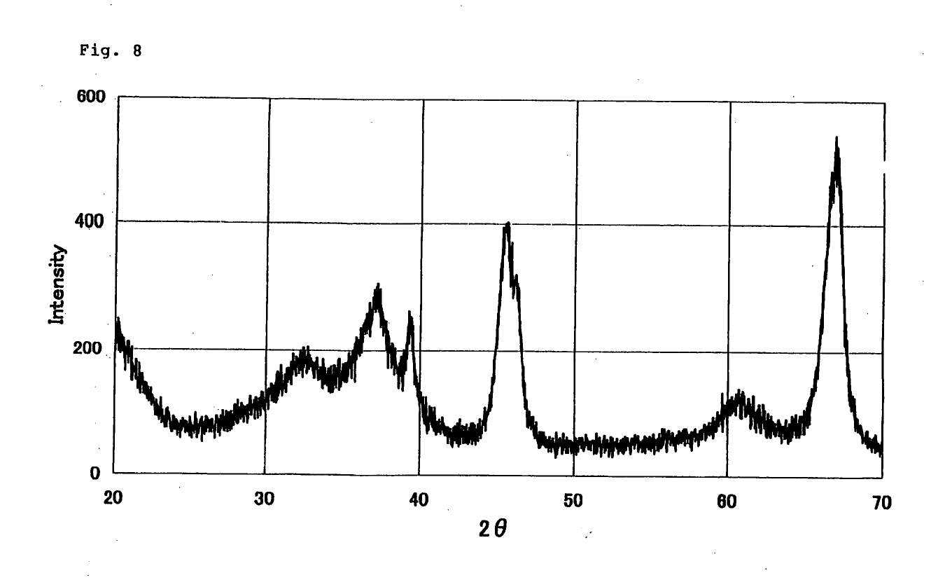

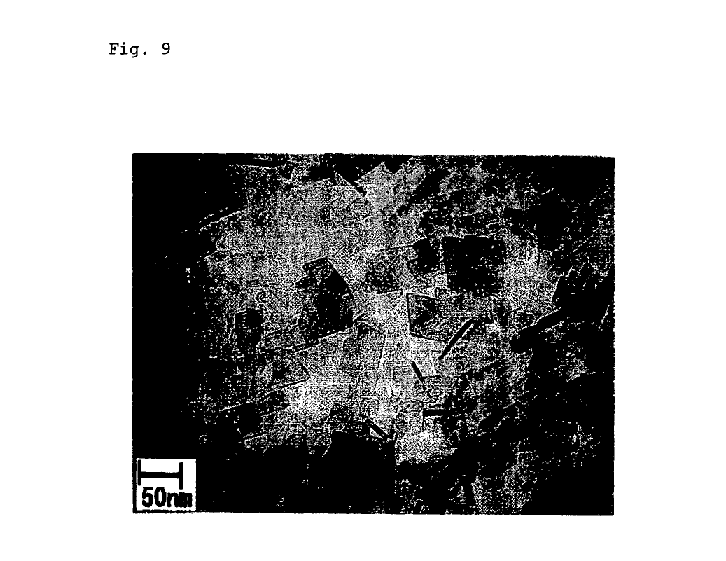

FIG. 8 shows the X-ray diffraction spectrum of the aluminum oxide particles, and FIG. 9 shows the transmission electron microphotograph of the particles (magnification: 200,000 times). The synthesis conditions for preparing the aluminum oxide particles, the crystal structure of the particles examined by X-ray diffraction, and the average particle size and the shape of the particles found from the transmission electron microphotograph of the particles are summarized in Table 3.

### Example 16

Aluminum oxide particles were obtained by forming a precipitate containing aluminum hydroxide, washing the precipitate with water, filtering and drying the product and subjecting the product to a heating treatment in the same manner as in the synthesis of the aluminum oxide particles of Example 15, except that the temperature for the heating treatment of the product of the hydrothermal treatment was changed from 600° C. to 1,000° C.

As a result of the measurement of the X-ray diffraction spectrum of the resultant aluminum oxide particles, a spectrum corresponding to 6-alumina which had a peak intensity higher than that of the spectrum observed in Example 15. The shapes of the aluminum oxide particles were observed with a transmission electron microscope. As a result, they are rectangle plate-form particles with a particle size of 30 to 50 nm, as well as Example 15.

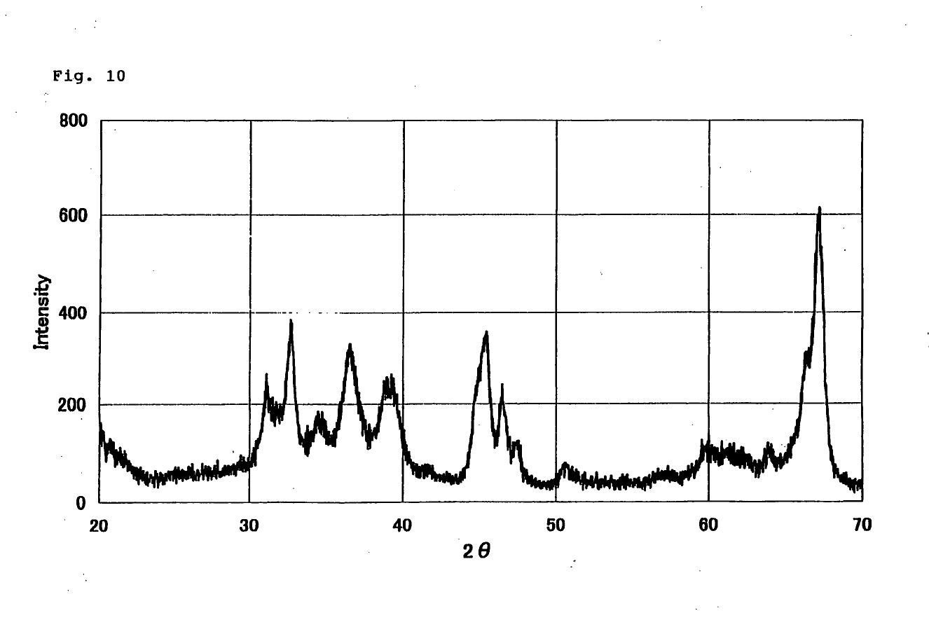

FIG. 10 shows the X-ray diffration spectrum of the aluminum oxide particles. The synthesis conditions for preparing the aluminum oxide particles, the crystal structure of the particles examined by X-ray diffraction, and the average particle size and the shape of the particles found from the transmission electron microphotograph of the particles are summarized in Table 3.

### Example 17

Aluminum oxide particles were obtained by forming a precipitate containing aluminum hydroxide, washing the precipitate with water, filtering and drying the product and subjecting the product to a heating treatment in the same manner as in the synthesis of the aluminum oxide particles of Example 15, except that the time for the hydrothermal treatment was changed from 2 hours to 4 hours.

As a result of the measurement of the X-ray diffraction spectrum of the resultant aluminum oxide particles, a spectrum corresponding to y-alumina was observed, as well as Example 15. The shapes of the aluminum oxide particles were further observed with a transmission electron microscope. As a result, they were rectangle plate-form particles with a particle size of 10 to 20 nm.

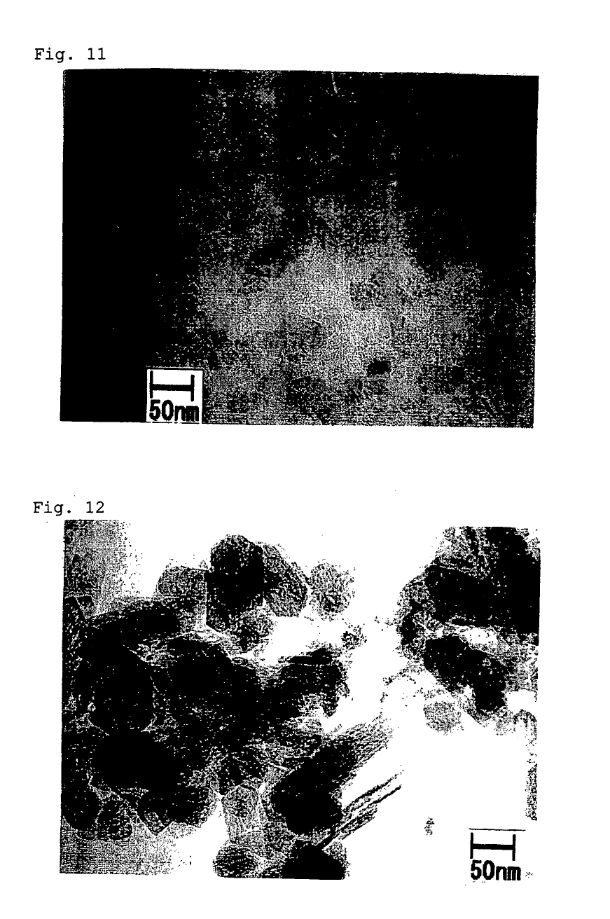

FIG. 11 is the transmission electron microphotograph of the aluminum oxide particles (magnification: 200,000times). The synthesis conditions, the crystal structure of the particles examined by X-ray diffraction, and the average particle size and the shape of the particles found from the transmission electron microphotograph of the particles are summarized in Table 3.

### Example 18

Aluminum oxide particles were obtained in the same manner as in Example 15 except for the following. That is, a precipitate containing aluminum hydroxide was formed by adding dropwise the aqueous aluminum chloride solution to the alkaline solution, and was adjusted in pH to 8.3 by adding dropwise hydrochloric acid. The precipitate was aged, washed with water in an amount about 1,000 times larger than the volume of the suspension of the precipitate, and again adjusted in pH to 8.1 by adding an aqueous sodium hydroxide solution. The steps following the hydrothermal treatment were carried out in the same manner as in Example 15 to obtain the aluminum oxide particles.

As a result of the measurement of the X-ray diffraction spectrum of the resultant aluminum oxide particles, a spectrum corresponding to y-alumina was observed, as well as Example 15. The shapes of the aluminum oxide particles were observed with a transmission electron microscope. As a result, they are hexagonal plate-form particles with a particle size of 65 to 85 nm.

FIG. 12 shows the transmission electron microphotograph of the particles (magnification: 200,000 times). The synthesis conditions, the crystal structure of the particles examined by X-ray diffraction, and the average particle size and the shape of the particles found from the transmission electron microphotograph of the particles are summarized in Table 3.

### Example 19

Aluminum oxide particles were obtained in the same manner as in Example 15, except the following. A precipitate was subjected to a hydrothermal treatment, and thereto was added an aqueous 4N sodium silicate solution (0.04 g). The mixture was sufficiently stirred, and to the reaction solution was added gradually an aqueous 0.8N hydrochloric acid solution while stirring the solution, so as to adjust the pH of the solution to 7.5. Other than those, the formation of the precipitate containing aluminum hydroxide, the washing of the precipitate with water, and the filtering, drying and heating treatment of the product were carried out in the same manner as in the synthesis of the aluminum oxideparticles of Example 15 to obtain the aluminum oxide particles.

As a result of the measurement of the X-ray diffraction spectrum of the resultant aluminum oxide particles, a spectrum corresponding to γ-alumina was observed. The shapes of the aluminum oxide particles were observed with a transmission electron microscope. As a result, they are rectangle plate-form particles with a particle size of 30 to 50 nm.

The synthesis conditions, the crystal structure of the particles examined by X-ray diffraction, and the average particle size and the shape of the particles found from the transmission electron microphotograph of the particles are summarized in Table 3.

### Example 20

The aluminum oxide particles obtained in Example 15 were further subjected to a heating treatment at 1,250° C. in an air for one hour. As a result of the measurement of the X-ray diffraction spectrum of the resultant aluminum oxide particles, a spectrum corresponding to α-alumina was observed. The shapes of the aluminum oxide particles were observed with a transmission electron microscope. As a result, they are rectangle plate-form particles with a particle size of 40 to 60 nm.

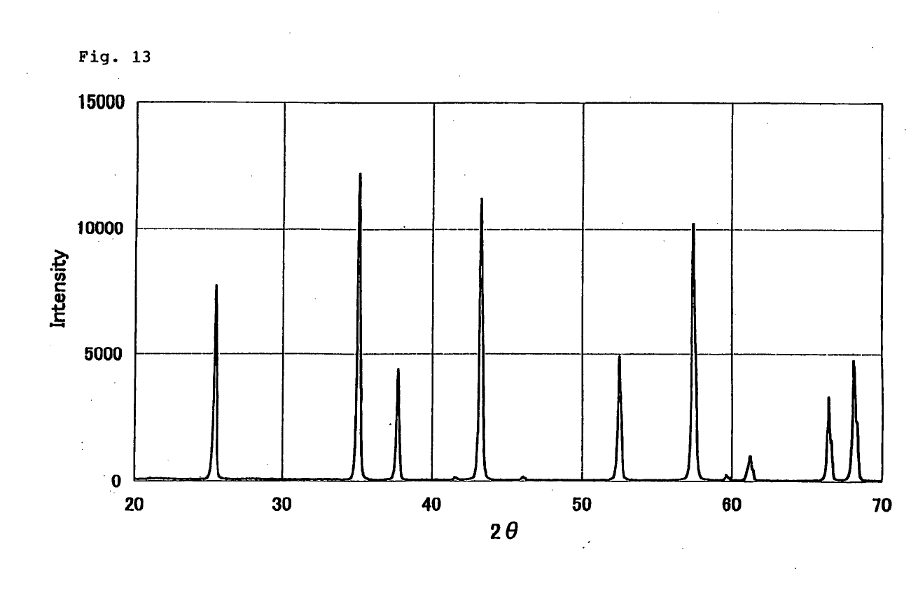

FIG. 13 shows the X-ray diffraction spectrum of the aluminum oxide particles, and FIG. 14 shows the transmission electron microphotograph of the particles (magnification: 200,000 times). The synthesis conditions, the crystal structure of the particles examined by X-ray diffraction, and the average particle size and the shape of the particles found from the transmission electron microphotograph of the particles are summarized in Table 3.

### Example 21

Aluminum oxide particles were obtained as follows:

A precipitate was formed in the same manner as in the synthesis of the aluminum oxide particles of Example 15, except that the amount of sodium hydroxide added was changed from 0.75 mol to 0.90 mol, and that no 2-aminoethanol was added. The suspension of the precipitate was aged, and then subjected to a hydrothermal treatment, washed with water, filtered and dried. The resulting product was further subjected to a heating treatment to obtain the aluminum oxide particles.

As a result of the measurement of the X-ray diffraction spectrum of the resultant aluminum oxide particles, a spectrum corresponding to y-alumina was observed. The shapes of the aluminum oxide particles were observed with a transmission electron microscope. As a result, they were found to be rectangle plate-form particles with a particle size of 40 to 60 nm, which was a slightly wide particle size distribution.

The synthesis conditions, the crystal structure of the particles examined by X-ray diffraction, and the average particle size and the shape of the particles found from the transmission electron microphotograph of the particles are summarized in Table 3.

### Comparative Example 3

Aluminum oxide particles were obtained in the same manner as in the synthesis of the aluminum oxide particles of Example 15, except that the temperature for the heating treatment was changed from 600° C. to 300° C.

As a result of the measurement of the X-ray diffraction spectrum of the resultant aluminum oxide particles, it was found that the transformation of the crystal structure to aluminum oxide was insufficient, and a spectrum corresponding to aluminum hydroxyoxide (boehmite: AIO(OH)) was observed.

The synthesis conditions, the crystal structure of the particles examined by X-ray diffraction, and the average particle size and the shape of the particles found from the transmission electron microphotograph of the particles are summarized in Table 3.

### Comparative Example 4

A precipitate containing aluminum hydroxide was formed under the same conditions as in Example 15, and was washed with water in an amount about 1,000 times larger than the volume of the suspension of the precipitate. Then, the pH of the suspension was again adjusted to 10.0 by adding an aqueous sodium hydroxide solution as in Example 15. Next, the suspension of the precipitate was subjected to a heating treatment at 90° C. for 2 hours, instead of a hydrothermal treatment in an autoclave. The resultant product was filtered, dried at 90° C. in an air, lightly crushed in a mortar, and subjected to a heating treatment at 60° C. in an air for one hour as in Example 1 to obtain aluminum oxide particles. After the heating treatment, the aluminum oxide particles were further washed with water, using an ultrasonic disperser, filtered and dried so as to remove the unreacted substance and the residue.

As a result of the measurement of the X-ray diffraction spectrum of the resultant aluminum oxide particles, a spectrum corresponding to γ-alumina was observed. The shapes of the aluminum oxide particles were observed with a transmission electron microscope. As a result, the shapes of the particles were granular or mass-like irregular and had a wide particle size distribution including fine particles with a particle size of about 20 nm, and sintered or agglomerated particles with a particle size of several micrometers.

The synthesis conditions for preparing the aluminum oxide particles, the crystal structure of the particles examined by X-ray diffraction, and the average particle size and the shape of the particles found from the transmission electron microphotograph of the particles are summarized in Table 3.

(Results of Observation of Aluminum Oxide Particles with a Transmission Electron Microscope)

FIGS. 9, 11, 12 and 14 are the transmission electron microphotographs of the aluminum oxide particles obtained in Examples 15, 17, 18 and 20, respectively.

The hydrothermal treatments of Examples 15 and 17 were carried out for 2 hours and 4 hours, respectively. In this regard, it is seen that, as the time of the hydrothermal treatment increases, the average particles size of the aluminum oxide particles formed after the heating treatment tends to decrease from about 45 nm to about 16 nm. This tendency indicates that, when the crystal growth of aluminum oxide during the hydrothermal treatment is sufficient, the crystal growth thereof tends to be suppressed during the following heating treatment, and that, when the crystal growth of aluminum oxide during the hydrothermal treatment, on the contrary, is suppressed, the crystal growth thereof tends to be facilitated during the following heating treatment.

As described above, one of the features of the process of the present invention is that the step for regulating the shapes and a particle size of the particles is done separately from the step for extracting the properties inherent to the material to the maximum. The initial step of the hydrothermal treatment has a close relationship with the post-step of the heating treatment in an air, and this relationship was, for the first time, discovered in the present invention.

Further, in Examples 15 and 18, the pH values of the precipitates found in the aging and the hydrothermal treatment are 10.2 and 8.3, respectively. The shapes of the aluminum particles are rectangle plate-form at pH 10.2, and are hexagonal plate-form at pH 8.3. The particle size tends to diminish and the particle shape tends to transform from hexagonal plates to rectangle plates, as the pH increases. In the state of the present art, the causes of the change in particle size and the transformation of the particle shape depending on the pH of the precipitate in the aging and the hydrothermal treatment are not elucidated. However, it is one of the distinguishing features of the process of the present invention, which is not found in other conventional processes, that the particle shape and the average particle size can be changed while the plate-form shapes of the particles being maintained, by controlling the values of pH in the aging or the hydrothermal treatment.

The synthesis conditions for preparing the aluminum oxide particles, the crystal structure of the particles examined by X-ray diffraction, and the average particle size and the shape of the particles found from the transmission electron microphotograph of the particles are summarized in Table 3. In this regard, the average particle size evaluated from the photograph was determined from the average particle size of 300 particles in the photograph.

(X-ray Diffraction Spectrum of Aluminum Oxide Particles)

FIGS. 8, 10 and 13 show the X-ray diffraction spectra of the aluminum oxide particles obtained in Examples 15, 16 and 20, which correspond to the X-ray diffraction spectra of γ-alumina, 67-alumina and a-alumina, respectively. These results suggest that when the conditions of the heating treatment are controlled, it is possible to obtain aluminum oxide particles with desired crystal structures without changing the particle size and particle shape of the aluminum oxide particles. This point is also one of the distinguishing features of the present invention.

TABLE 3

| | | | Temp. (° C.)/ | | | | |
|---|---|---|---|---|---|---|---|
| | | | time (hr.) | Temp. (° C.)/ | | | |
| | Crystal | PH in | of | time (hr.) | | | Av. |
| | growth-controlling | precipitating | hydro-thermal | of heating | Crystal | | particle |
| | agent | step | treatment | treatment | structure | Shape of particle | size (nm) |
| Ex. 15 | 2-amino-ethanol | 10.2 | 200/2 | 600/1 | γ-alumina | rectangle plate | 45 |
| Ex. 16 | 2-amino-ethanol | 10.2 | 200/2 | 1,000/1 | δ-alumina | rectangle plate | 40 |
| Ex. 17 | 2-amino-ethanol | 10.2 | 200/4 | 600/1 | γ-alumina | rectangle plate | 16 |
| Ex. 18 | 2-amino-ethanol | 8.3 | 200/2 | 600/1 | γ-alumina | hexagonal plate | 70 |
| Ex. 19 | 2-amino-ethanol & | 10.2 | 200/2 | 600/1 | γ-alumina | rectangle plate | 35 |
| | sodium silicate | | | | | | |
| Ex. 20 | 2-amino-ethanol | 10.2 | 200/2 | 1,250/1 | α-alumina | rectangle plate | 48 |
| Ex. 21 | None | 10.6 | 200/2 | 600/1 | γ-alumina | rectangle plate | 52 |
| Com. Ex. 3 | 2-amino-ethanol | 10.2 | 200/2 | 300/1 | boehmite | rectangle plate | 42 |
| Com. Ex. 4 | 2-amino-ethanol | 10.2 | no | 600/1 | γ-alumina | agglomerated | 500 |
| | | | treatment | | | | |

As is apparent from Table 3, all the aluminum oxide particles obtained in the above Examples were plate-form shaped, and it is known from the X-ray diffraction analyses that it is possible to control the crystal structure of aluminum oxide particles to γ, δ, α or the like by controlling the conditions for the heating treatment.

On the other hand, aluminum oxide particles could not be obtained in Comparative Example 3, and the resultant particles were left to be the aluminum hydroxyoxide particles (boehemite particles) Further, the aluminum oxide particles of Comparative Example 4 had a very wide particle size distribution: the sintered or agglomerated particles with very large particle sizes were included. Thus, it is seen that the aluminum oxide particles of Comparative Example 4 are not suitable for use as additives such as abrasive members and the like.

The particle sizes of the aluminum oxide particles of the present invention are within the ranges optimal for not only abrasive members such as abrasive sheets and abrasive liquids but also additive particles for magnetic tapes and a variety of functional sheets. Hitherto, aluminum oxide particles which concurrently have plate-form shapes and particle sizes of so fine as 100 nm or less have not been realized, and will be used for quite new applications which are believed to be impossible so far.

### (4) Examples of Silicon Oxide Particles

### Example 22

An alkaline aqueous solution was prepared by dissolving sodium metasilicate (0.074 mol) and 2-aminoethanol (100 ml) in water (800 ml). Separately, an aqueous 1N hydrochloric acid solution (400 ml) was prepared. To the alkaline aqueous solution was added dropwise the aqueous hydrochloric acid solution until the pH of the resulting suspension was adjusted to 8.3, to form a precipitate containing silicon hydroxide at about 25° C. Then, the precipitate in the state of the suspension was aged for 20 hours and then washed with water until the pH reached 7.6.

Next, the supernatant was removed, and the suspension of the precipitate was charged in an autoclave and subjected to a hydrothermal treatment at 200° C. for 2 hours.

The resultant product was filtered, dried at 90° C. in an air, lightly crushed in a mortar, and subjected to a heating treatment at 800° C. in an air for one hour to obtain silicon oxide particles.

The shapes of the silicon oxide particles were observed with a transmission electron microscope. As a result, they were almost disk-like particles with a particle size of 30 to 40 nm.

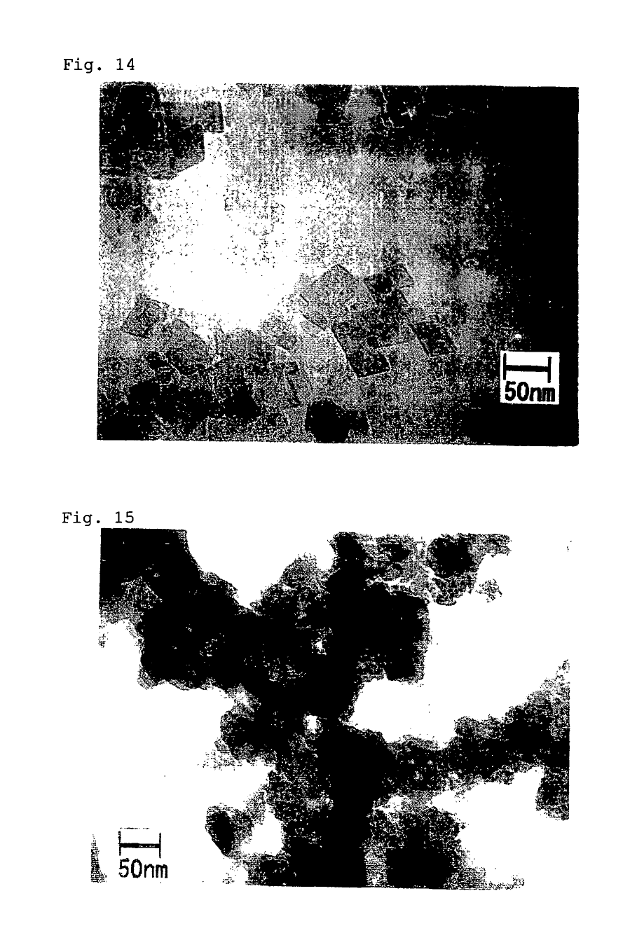

FIG. 15 shows the transmission electron microphotograph of the particles (magnification: 200,000 times). The synthesis conditions for preparing the silicon oxide particles, the crystal structure of the particles examined by X-ray diffraction, and the average particle size and the shape of the particles found from the transmission electron microphotograph of the particles are summarized in Table 4.

### Example 23

Silicon oxide particles were obtained by forming a precipitate containing silicon hydroxide, washing the precipitate with water, filtering, drying and subjecting the product to a heating treatment in the same manner as in the synthesis of the silicon oxide particles of Example 22, except that the temperature for the heating treatment of the product of the hydrothermal treatment was changed from 800° C. to 600° C.

The shapes of the silicon oxide particles were observed with a transmission electron microscope. As a result, they were almost disc-like particles with a particle size of 15 to 25 nm. The synthesis conditions for preparing the silicon oxide particles, the crystal structure of the particles examined by X-ray diffraction, and the average particle size and the shape of the particles found from the transmission electron microphotograph of the particles are summarized in Table 4.

### Example 24

Silicon oxide particles were obtained by forming a precipitate containing silicon hydroxide, washing the precipitate with water, filtering, drying and subjecting the product to a heating treatment in the same manner as in the synthesis of the silicon oxide particles of Example 22, except that the temperature for the heating treatment of the product of the hydrothermal treatment was changed from 800° C. to 1,000° C.

The shapes of the silicon oxide particles were observed with a transmission electron microscope. As a result, they were almost disc-like particles with a particle size of 70 to 100 nm. The synthesis conditions for preparing the silicon oxide particles, the crystal structure of the particles examined by X-ray diffraction, and the average particle size and the shape of the particles found from the transmission electron microphotograph of the particles are summarized in Table 4.

### Example 25

Silicon oxide particles were obtained as follows:

In the synthesis of the silicon oxide particles of Example 22, the product of the hydrothermal treatment was washed with water in an amount 500 times larger than the volume of the suspension of the precipitate, and filtered and dried. The pH of the product found after the washing was 7.5. The steps following the heating treatment were carried out in the same manner as in Example 22.

The shapes of the silicon oxide particles were observed with a transmission electron microscope. As a result, they were almost disc-like particles with a particle size of 30 to 40 nm. The synthesis conditions for preparing the silicon oxide particles, the crystal structure of the particles examined by X-ray diffraction, and the average particle size and the shape of the particles found from the transmission electron microphotograph of the particles are summarized in Table 4.

### Example 26

Silicon oxide particles were obtained in the same manner as in Example 22, except that the particles obtained by the heating treatment at 80° C. in an air for one hour were further washed water, using an ultrasonic disperser.

The shapes of the silicon oxide particles were observed with a transmission electron microscope. As a result, they were almost disc-like particles with a particle size of 30 to 40 nm. The synthesis conditions for preparing the silicon oxide particles, the crystal structure of the particles examined by X-ray diffraction, and the average particle size and the shape of the particles found from the transmission electron microphotograph of the particles are summarized in Table 4.

### Example 27

A precipitate containing silicon hydroxide was formed by adding dropwise an aqueous iN hydrochloric acid solution to an aqueous sodium metasilicate solution until the pH reached 7.5, in the same manner as in the synthesis of the silicon oxide particles of Example 22, except that the alkaline aqueous solution prepared by dissolving only sodium metasilicate (0.074 mol) in water (800 ml) without 2-aminoethanol was used instead of the alkaline aqueous solution of sodium metasilicate (0.074 mol) and 2-aminoethanol (100 ml) in water (800 ml). Then, the resulting precipitate in the state of the suspension was aged for 20 hours and then washed with water until the pH reached 7.6.

Next, the supernatant was removed, and the suspension of the precipitate was charged in an autoclave and subjected to a hydrothermal treatment at 200° C. for 2 hours.

The shapes of the resultant silicon oxide particles were observed with a transmission electron microscope. As a result, they were almost disk-like particles with a particle size of 20 to 30 nm, although having a slightly wide particle size distribution. The synthesis conditions for preparing the silicon oxide particles, the crystal structure of the particles examined by X-ray diffraction, and the average particle size and the shape of the particles found from the transmission electron microphotograph of the particles are summarized in Table 4.

### Comparative Example 5

A precipitate containing silicon hydroxide was formed and directly washed with water, filtered, dried and subjected to a heating treatment in the same manner as in the synthesis of the silicon oxide particles of Example 22, except that the hydrothermal treatment of the precipitate was not carried out. Thus, silicon oxide particles were obtained.

The shapes of the resultant silicon oxide particles were observed with a transmission electron microscope. As a result, it was found that the particles were sintered or agglomerated particles, and thus, that such particles had a very wide particle size distribution of 1 to 10 μm. The synthesis conditions for preparing the silicon oxide particles, the crystal structure of the particles examined by X-ray diffraction, and the average particle size and the shape of the particles found from the transmission electron microphotograph of the particles are summarized in Table 4. The average particle size evaluated from the transmission electron microphotograph was calculated from 300 particles in the photograph.

(Results of Observation of Silicon Oxide Particles with a Transmission Electron Microscope)

FIG. 15 is the transmission electron microphotograph of the silicon oxide particles obtained in Example 22. It is seen from the photograph that the silicon oxide particles were almost disc-like shaped particles with a particle size of 30 to 40 nm. Hitherto, it has been very difficult to form such plate-form silicon oxide particles with very small particle sizes by any of conventional processes, and the process of the present invention has, for the first time, succeeded in forming such particles.

TABLE 4

| | | | Temp. (° C.)/ | | | | |
|---|---|---|---|---|---|---|---|
| | | | time (hr.) | Temp. (° C.)/ | | | |
| | Crystal | PH in | of | time (hr.) | | | |
| | growth-controlling | precipitating | hydro-thermal | of heating | Crystal | Shape of | Av. particle |
| | agent | step | treatment | treatment | structure | particle | size (nm) |
| Ex. 22 | 2-amino-ethanol | 8.3 | 200/2 | 800/1 | amorphous | disc-like | 34 |
| Ex. 23 | 2-amino-ethanol | 8.3 | 200/2 | 600/1 | amorphous | disc-like | 21 |
| Ex. 24 | 2-amino-ethanol | 8.3 | 200/2 | 1,000/1 | amorphous | disc-like | 85 |
| Ex. 25 | 2-amino-ethanol | 8.3 | 200/2 | 800/1 | amorphous | disc-like | 34 |
| Ex. 26 | 2-amino-ethanol | 8.3 | 200/2 | 80/1 | amorphous | disc-like | 31 |
| Ex. 27 | No addition | 7.5 | 200/2 | 80/1 | amorphous | disc-like | 22 |
| Com. Ex. 5 | 2-amino-ethanol | 8.3 | No | 800/1 | amorphous | agglomerated | >1,000 |
| | | | treatment | | | | |

As is apparent from Table 4, the silicon oxide particles obtained in the above Examples were found to be amorphous in crystal structure from the X-ray diffraction spectra, however, had plate-form shapes. Such plate-form shaped silicon oxide particles have been realized by the present invention for the first time.

On the other hand, the silicon oxide particles of Comparative Example 5 had large particle sizes due to the sintering or agglomeration, and also had a very wide particle size distribution. Therefore, the silicon oxide particles of Comparative Example 5 are not suitable for the use as abrasive members and the like.

The particle sizes of the silicon oxide particles of the present invention are within the ranges optimal for not only abrasive members for abrasive sheets and abrasive liquids but also additive particles for magnetic tapes and a variety of functional sheets. Hitherto, silicon oxide particles which concurrently have unique plate-form shapes and particle sizes of so fine as 100 nm or less have not been realized, and will find quite new applications which are believed to be impossible so far.

### (5) Examples of Iron Oxide Particles

### Example 28

The following two different aqueous solutions were prepared.

| | | | |
|---|---|---|---|
| Solution A: | Ferric chloride (FeCl₃.6H₂O) | 20 | g |
| | Water | 500 | cc |
| Solution B: | Sodium hydroxide | 30 | g |
| | Monoethanolamine | 50 | cc |
| | Water | 1,000 | |

The solution A was added dropwise into the solution B in about one hour while stirring and maintaining the solutions A and B at 12° C. After completion of the dropwise addition, the mixture was further stirred for one hour. The resultant precipitate was left to stand at room temperature for about 20 hours, washed with pure water, adjusted in pH to 11.3 by the addition of an aqueous sodium hydroxide solution, and subjected to a hydrothermal treatment at 150° C. for one hour in an autoclave. Plate-form goethite (α-FeOOH) was obtained by this treatment. To the goethite was added a sodium silicate solution in an amount of 1 wt. % in terms of SiO₂ based on the weight of the goethite, while being stirred. Hydrochloric acid was added to the solution to adjust the pH to 7.3. Thus, the resultant particles were coated with SiO₂, and filtered, dried and dehydrated by heating at 600° C. in an air for one hour. Plate-form α-iron oxide particles (x-Fe₂O₃) were obtained by this heating treatment.

The resultant plate-form (α-iron oxide particles were disc-like or hexagonal plate-form particles with an average particle size of 65 nm which had pores with diameters of about 30 nm at and around their center portions. It is seen from the X-ray diffraction spectrum that they were alpha hematite having corundum structures.

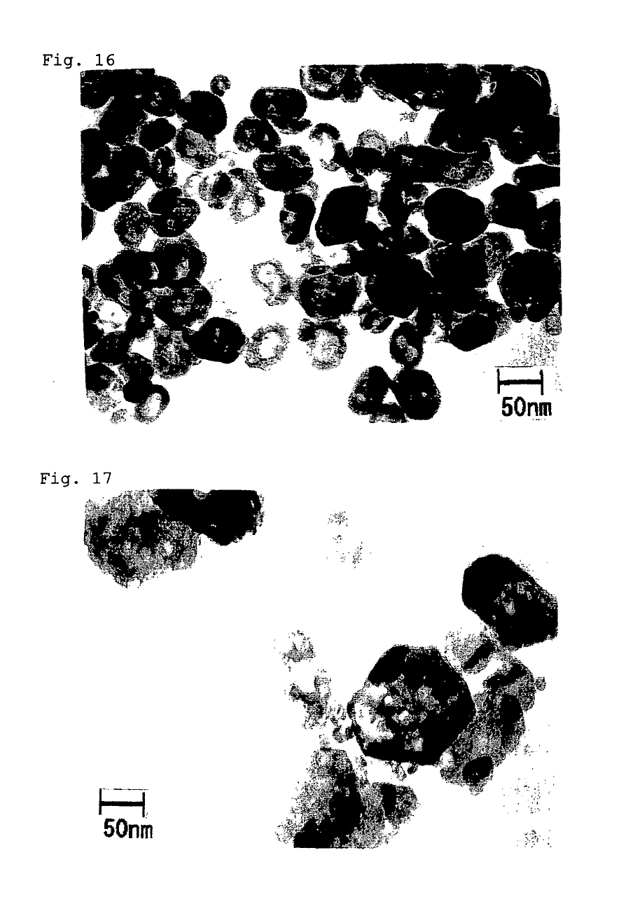

FIG. 16 is the electron microphotograph of the iron oxide particles. The synthesis conditions for the iron oxide particles, the crystal structure thereof, and the average particle size and shape thereof found from the transmission electron microphotograph are summarized in Table 5.

### Example 29

A precipitate was formed in the same manner as in Example 28, except that the temperature for maintaining both solutions A and B during the dropwise addition of the solution A into the solution B was changed from 12° C. to 18° C. The resultant precipitate was then subjected to a hydrothermal treatment, and dehydrated by heating in the same manner as in Example 28 to obtain disc-like or hexagonal plate-form iron oxide particles with an average particle size of 90 nm, having pores therein. The iron oxide particles were found to be alpha hematite with a corundum structure, from the X-ray diffraction spectrum.

FIG. 17 is the electron microphotograph of the iron oxide particles. The synthesis conditions for the iron oxide particles, the crystal structure thereof, and the average particle size and shape thereof found from the transmission electron microphotograph are summarized in Table 5.

### Comparative Example 6

A precipitate was formed by adding dropwise the solution A into the solution B as in the synthesis of the iron oxide particles of Example 28, and the precipitate was coated with SiO₂ without undergoing the hydrothermal treatment, filtered, dried and dehydrated by heating at 600° C. in an air for one hour.

Iron oxide particles obtained by this heating treatment had granular shapes and an average particle size of 60 nm, and were not plate-form shaped unlike the particles of Examples 28 and 29. The synthesis conditions for the iron oxide particles, the crystal structure thereof, and the average particle size and shape thereof found from the transmission electron microphotograph are summarized in Table 5.

(Results of Observation of Iron Oxide Particles with a Transmission Electron Microscope)

FIGS. 16 and 17 are the transmission electron microphotographs of the iron oxide particles obtained in Examples 28 and 29, respectively. The iron oxide particles of Example 28 shown in FIG. 16 were found to be plate-form particles with an average particle size of 65 nm, and the iron oxide particles of Example 29shown in FIG. 17 were found to be plate-form particles with an average particle size of 90 nm. Either of the iron oxide particles have pores therein. The pores were formed because of the dehydration while the plate-form goethite particles obtained by the hydrothermal treatment were being subjected to the heating treatment. The shapes and sizes of the pores formed by heating and dehydrating the plate-form hydroxide particles vary depending on the types of materials used: i.e., such pores include from very fine micro pores to relatively large pores as found in the plate-form iron oxide particles of the present invention. However, the formation of such pores does not impair the features of the plate-form particles, such as abrading properties, etc., of the present invention, in any way.

TABLE 5

| | | | Temp. (° C.)/ | | | | |
|---|---|---|---|---|---|---|---|
| | | PH/temp. | time (hr.) | Temp. (° C.)/ | | | |
| | Crystal | (° C.) in | of | time (hr.) | | | |
| | growth-controlling | precipitating | hydro-thermal | of heating | Crystal | Shape of | Av. particle |
| | agent | step | treatment | treatment | structure | particle | size (nm) |
| Ex. 28 | 2-amino-ethanol & | 11.3/12 | 150/2 | 600/1 | α-Fe₂O₃ | disc-like to | 65 |
| | sodium silicate | | | | | hexagonal plate | |
| Ex. 29 | 2-amino-ethanol & | 11.3/18 | 150/2 | 600/1 | α-Fe₂O₃ | disc-like to | 90 |
| | sodium silicate | | | | | hexagonal plate | |
| Com. Ex. 6 | 2-amino-ethanol & | 11.3/12 | No | 600/1 | α-Fe₂O₃ | granular | 60 |
| | sodium silicate | | treatment | | | | |

As is apparent from Table 5, the iron oxide particles obtained in the above Examples were found to have a corundum structure and to be plate-form particles. Iron oxide particles with such shapes have been realized for the first time by the present invention.

On the other hand, the iron oxide particles of Comparative Example 6 were granular and were not formed with such plate-form shapes as seen in the present invention.

The particle sizes of the iron oxide particles of the present invention are within the ranges optimal for not only abrasive members for abrasive sheets and abrasive liquids but also additive particles for magnetic tapes and a variety of functional sheets. Hitherto, silicon oxide particles which concurrently have unique plate-form shapes and particle sizes of so fine as 100 nm or less have not been realized, and will find quite new applications which are believed to be impossible so far.

### (6) Examples of Application to Abrasive Tape

Next, examples of application of the plate-form oxide particles of the present invention to an abrasive tape as one of abrasive members will be described. The abrasive tape is provided by forming an abrasive layer containing an abrasive material on the surface of a film-like or sheet-like support, and cutting the resulting lamination sheet into tapes with predetermined widths. The only different point of the abrasive tape from an abrasive sheet and an abrasive film is in the form thereof. Accordingly, the application of the plate-form oxide particles of the present invention to abrasive sheets and abrasive films also provides similar effects as described in the following examples.

### Examples 30 to 44, and Comparative Examples 7 to 16

Abrasive coating liquids for abrasive layers, having the following compositions, were prepared by using the plate-form oxide particles of the present invention and the oxide particles of Comparative Examples, respectively.

The oxide particles used in the experiments were prepared by carrying out the experiments of Example 1 and the like on larger scales. (The rest were done in the same manner.)

<<Components of a coating liquid for forming
an abrasive layer>>

| | | |
|---|---|---|
| Non-magnetic oxide particles | 200 | parts |
| Vinyl chloride-vinyl acetate copolymer | 30 | parts |
| (“VAGH” manufactured by UCC) | | |
| Polyurethane resin | 25 | parts |
| (“Viron UR8300” manufactured by TOYOBO CO., LTD.) | | |
| Methyl ethyl ketone | 150 | parts |
| Toluene | 150 | parts |
| Cyclohexanone | 130 | parts |

(“Parts” are “wt. Parts”, Unless Otherwise Specified.)

The above components of the coating liquid were mixed and stirred, and the resulting mixture was dispersed in a sand mill to prepare a coating liquid for use in forming an abrasive layer. The coating liquid was applied on one side of a support of a polyethylene terephthalate film with a thickness of 75 μm so that the thickness of the resultant layer of the coating liquid could be 10 μm after calendered. The layer was dried and planished by calendering. The resultant lamination sheet was cut into tapes with predetermined widths to provide abrasive tapes.

Table 6 shows the kinds of the abrasive tapes and the main properties of the oxide particles used in these abrasive tapes.

TABLE 6

| | | Properties of Oxide Particles Used | | |
|---|---|---|---|---|
| | | | | Average |
| Ex. No./Com. Ex. | | | Shape of | particle |
| No. | | Kind | Particles | size (nm) |
| Ex. 30 | Ex. 1 | cerium oxide | hexagonal plate | 13 |
| Ex. 31 | Ex. 3 | cerium oxide | hexagonal-rectangle | 32 |
| | | | plate | |
| Ex. 32 | Ex. 7 | cerium oxide | hexagonal plate | 20 |
| C. Ex. 7 | C. Ex. 1 | cerium oxide | agglomerated | >1,000 |
| C. Ex. 8 | — | cerium oxide | granular | ca. 100 |
| Ex. 33 | Ex. 8 | zirconium oxide | hexagonal | 19 |
| | | | plate-form | |
| Ex. 34 | Ex. 9 | zirconium oxide | hexagonal | 25 |
| | | | plate-form | |
| Ex. 35 | Ex. 14 | zirconium oxide | hexagonal | 20 |
| | | | plate-form | |
| C. Ex. 9 | C. Ex. 2 | zirconium oxide | agglomerated | >1,000 |
| C. Ex. 10 | — | zirconium oxide | granular | ca. 40 |
| Ex. 36 | Ex. 15 | aluminum oxide | rectangle | 38 |
| | | (γ-alumina) | plate-form | |
| Ex. 37 | Ex. 17 | aluminum oxide | rectangle | 17 |
| | | (γ-alumina) | plate-form | |
| Ex. 38 | Ex. 18 | aluminum oxide | hexagonal | 70 |
| | | (γ-alumina) | plate-form | |
| Ex. 39 | Ex. 20 | aluminum oxide | rectangle | 48 |
| | | (α-alumina) | plate-form | |
| Ex. 40 | Ex. 21 | aluminum oxide | rectangle | 52 |
| | | (γ-alumina) | plate-form | |
| C. Ex. 11 | C. Ex. 4 | aluminum oxide | agglomerated | 500 |
| | | (γ-alumina) | | |
| C. Ex. 12 | — | aluminum oxide | granular | ca. 80 |
| | | (α-alumina) | | |
| Ex. 41 | Ex. 22 | silicon oxide | disc-like | 34 |
| | | (amorphous) | | |
| Ex. 42 | Ex. 27 | silicon oxide | disc-like | 22 |
| | | (amorphous) | | |
| C. Ex. 13 | C. Ex. 5 | silicon oxide | agglomerated | >1,000 |
| | | (amorphous) | | |
| C. Ex. 14 | — | silicon oxide | spherical | ca. 10 |
| | | (colloidal | | |
| | | silica) | | |
| Ex. 43 | Ex. 28 | iron oxide | rectangle-hexagonal | 65 |
| | | (α-hematite) | plate-form | |
| Ex. 44 | Ex. 29 | iron oxide | rectangle-hexagonal | 90 |
| | | (α-hematite) | plate-form | |
| C. Ex. 15 | C. Ex. 6 | iron oxide | granular | 60 |
| | | (α-hematite) | | |
| C. Ex. 16 | — | iron oxide | cubic | 150 |
| | | (α-hematite) | | |

Examples and Comparative Examples in the right side of the column “Example/Comparative Example” in Table 6 mean that the oxide particles obtained in these Examples and Comparative Examples were used. Also, in Table 6, the abrasive tapes of Comparative Examples 8, 10, 12, 14 and 16 were made, using cerium oxide particles, zirconium oxide particles, aluminum oxide particles, silicon oxide particles and iron oxide particles, respectively, which were all commercially available and were compounded in the same components by the same method as used in the foregoing coating liquid for forming the abrasive layer. These oxide particles are all commercially available and sold as so-called fine particles with spherical, granular or cubic shapes. The abrasive tapes using these commercially available oxide particles were made for comparing the abrading properties of the abrasive tapes using the plate-form oxide particles featured by the present invention.

The abrasive tapes using the oxide particles of Examples and Comparative Examples were subjected to glass-flawing tests according to the following method, and the performance thereof were evaluated. The results are shown in Table 7.

(Flawing Test)

Both ends of an abrasive tape were fixed on a glass plate, and a glass ball with a diameter of 5 mm (NIKKATO CORPORATION) was reciprocally slid 100 times at a sliding speed of 3,000mm/min. with a sliding scale of 20mm under a load of 20 g, on the abrasive tape impregnated with water, using a surface tester (“HEIDON-14DR” manufactured by Shintokagaku). Then, the abrasion degree of the glass ball was observed with a microscope and evaluated based on five criteria. In this regard, the abrasion degree is larger as the criterion value increases. The abrasion flaws were evaluated based on four criteria by observing the surface of the glass ball with a microscope. The criteria of the abrasion flaws were determined as follows.

A: No flaw found on the surface of the glass ball.

B: Two or less flaws found on the surface of the glass ball.

C: Three or four flaws found on the surface of the glass ball.

D: Five or more flaws found on the surface of the glass ball.

TABLE 7

| | Abrasion degree | Evaluation of flaws |
|---|---|---|
| Ex. 30 | ca. 3 | A |
| Ex. 31 | 3 or 4 | B or A |
| Ex. 32 | ca. 3 | B or A |
| Com. Ex. 7 | ca. 4 | D |
| Com. Ex. 8 | 3 or 4 | C |
| Ex. 33 | ca. 3 | A |
| Ex. 34 | 3 or 4 | B or A |
| Ex. 35 | ca. 3 | B or A |
| Com. Ex. 9 | 4 or 5 | D |
| Com. Ex. 10 | ca. 4 | C |
| Ex. 36 | 3 or 4 | B or A |
| Ex. 37 | ca. 3 | B or A |
| Ex. 38 | 4 or 5 | B |
| Ex. 39 | 3 or 4 | B or A |
| Ex. 40 | ca. 4 | B |
| Com. Ex. 11 | ca. 5 | D |
| Com. Ex. 12 | ca. 5 | D |
| Ex. 41 | ca. 3 | A |
| Ex. 42 | 2 or 3 | A |
| Com. Ex. 13 | ca. 3 | C |
| Com. Ex. 14 | ca. 2 | A |
| Ex. 43 | ca. 3 | A |
| Ex. 44 | 3 or 4 | B or A |
| Com. Ex. 15 | ca. 3 | B |
| Com. Ex. 16 | 3 or 4 | C |

The results of Tables 6 and 7 clearly show the difference between the abrasive tapes using the plate-form oxide particles of the present invention and the abrasive tapes using the oxide particles of Comparative Examples which were subjected to the heating treatments alone without the hydrothermal treatments in case where the oxide particles of the same oxide were used in both cases. In other words, the abrasive tapes using the plate-form oxide particles of the present invention show less flaws while maintaining appropriate abrading properties, and thus were well balanced. On the other hand, the abrasive tapes using the oxide particles of Comparative Examples were found to be unsuitable for use in the abrasive tapes, since they were very susceptible to flawing in spite of their higher abrading properties because of their larger particle sizes.

In case where the abrasive tapes were made using the commercially available oxide particles of the same oxide and sold as very fine particles, such abrasive tapes were satisfactory in balance between the abrading properties and the degree of abrasion. However, the abrasive sheets made using the commercially available oxide particles were inferior in total evaluation of the properties, to the abrasive tapes made using the plate-form oxide particles with a particle size of 10 to 100 nm of the present invention.

This may be because the commercially available oxide particles were granular, spherical or cubic, while the oxide particles of the present invention were plate-form shaped. In particular, when the plate-form oxide particles of the present invention are used, the abrading properties are imparted to the tape, since the edges of the plate-form particles are effectively utilized, and the plate-form faces of the plate-form particles improve the conditions for contact with a surface to be polished. As a result, the excellent abrasive performance as mentioned above can be imparted.

Although it seems to be meaningless to make comparison between each of the oxide particles of the present invention, the aluminum oxide particles and the zirconium oxide particles have relatively higher abrading properties, and the cerium oxide particles, the iron oxide particles and the silicon oxide particles have relatively lower abrading properties. On the other hand, the evaluation of the flaw degrees of the above oxide particles is reversed to the evaluation of the abrading properties thereof. Therefore, the appropriate selection of the oxide particles in accordance with the end use is important. However, the abrasive tapes made using any of the plate-form oxide particles of the present invention with a particle size of 10 to 100 nm are superior in total evaluation of the properties, to the abrasive tapes made using the conventional granular, spherical or cubic oxide particles as mentioned above.

The foregoing Examples are described as being applied to the abrasive sheets by making good use of the excellent abrading properties of the oxide particles of the present invention. The oxide particles of the present invention, however, are not necessarily applied to the sheets, and are, of course, applied to abrasive liquids and abrasive slurry. That is, by making good use of the unique shapes of the non-magnetic oxide particles of the present invention, the oxide particles of the present invention can exhibit excellent properties as particles for abrasive members, independently of the final form thereof.

As mentioned above, it can be understood that the use of the plate-form cerium oxide, zirconium oxide, aluminum oxide, silicon oxide and iron oxide particles of the present invention with a particle size of 10 to 100 nm can provide good-balanced abrasive sheets which show less flaws due to abrasion while maintaining high abrading properties.

### (7) Examples of Application to a Coating Type Magnetic Recording Medium (Magnetic Tape)

Next, description is made on an example of applying the plate-form oxide particles of the present invention to an additive for a coating type magnetic tape as one of coating type magnetic recording media.

### Examples 45 to 49 and Reference Example 1

<<Components of coating composition for primer layer>>

| | | |
|---|---|---|
| (1) | | |
| Oxide particles (see Table 8 below) | 76 | parts |
| Carbon black | 24 | parts |
| (average particle size: 25 nm, and: | | |
| oil absorption 55 g/cc) | | |
| Stearic acid (lubricant) | 2.0 | parts |
| Vinyl chloride-hydroxypropyl acrylate copolymer | 8.8 | parts |
| (content of —SO₃Na groups: 0.7 × 10⁻⁴ eq./g) | | |
| Polyester-polyurethane resin | 4.4 | parts |
| (content of —SO₃Na groups: 1.0 × 10⁻⁴ eq./g) | | |
| Cyclohexanone | 25 | parts |
| Methyl ethyl ketone | 40 | parts |
| Toluene | 10 | parts |
| (2) | | |
| Butyl stearate (lubricant) | 1 | part |
| Cyclohexanone | 70 | parts |
| Methyl ethyl ketone | 50 | parts |
| Toluene | 20 | parts |
| (3) | | |
| Polyisocyanate (crosslinking agent) | 2.0 | parts |
| Cyclohexanone | 10 | parts |
| Methyl ethyl ketone | 15 | parts |
| Toluene | | |

<<Components of coating composition for magnetic layer>>

| | | |
|---|---|---|
| (1) | | |
| Ferromagnetic iron metal powder | 100 | parts |
| [Co/Fe: 25 wt. %, Y/Fe: 9.3 wt. %, | | |
| Al/Fe: 3.5 wt. %, Ca/Fe: 0 wt. %, | | |
| σs: 155 A.m²/kg, Hc: 188.2 kA/m, | | |
| pH: 9.4, average major axis length: 0.10 μm] | | |
| Vinyl chloride-hydroxypropyl acrylate copolymer | 12.3 | parts |
| (content of —SO₃Na groups: 0.7 × 10⁻⁴ eq./g) | | |
| Polyester-polyurethane resin | 5.5 | parts |
| (content of —SO₃Na groups: 1.0 × 10⁻⁴ eq./g) | | |
| α-alumina (average particle size: 0.12 m) | 10.0 | parts |
| Carbon black | 1.0 | part |
| (average particle size: 75 nm, and | | |
| DBP oil absorption: 72 cc/100 g) | | |
| Metal acid phosphate | 2 | parts |
| Amide palmitate | 1.5 | parts |
| n-Butyl stearate | 1.0 | part |
| Tetrahydrofuran | 65 | parts |
| Methyl ethyl ketone | 245 | parts |
| Toluene | 85 | parts |
| (2) | | |
| Polyisocyanate (crosslinking agent) | 2.0 | parts |
| Cyclohexanone | 167 | parts |

A coating composition for a primer layer was prepared from the above components of the coating composition for the primer layer, as follows: Firstly, the components (1) were kneaded with a kneader, and thereto were added the components (2). The mixture was stirred and dispersed for a residence time of 60 minutes in a sand mill. To the mixture were added the components (3), and they were stirred and filtered to give the coating composition for the primer layer. Separately, a coating composition for a magnetic layer was prepared from the above components of the coating composition for the magnetic layer, as follows: Firstly, the components (1) were kneaded with a kneader and dispersed for a residence time of 45 minutes in a sand mill. To the dispersion were added the components (2), and the mixture was stirred and filtered to give the magnetic coating composition.

Next, the above coating composition for the primer layer was applied on a non-magnetic substrate composed of a polyethylene naphthalate film (PEN having a thickness of 6.2 am, a humidity expansion coefficient of 5.6×10⁻⁶/% RH, a thermal expansion coefficient of −7.4×10⁻⁶/° C., MD of 6.50 GPa, and MD/TD of 0.54, manufactured by Teijin Limited, provided that MD means the Young's modulus of the film in the film-drawing direction (the lengthwise direction), and that TD means the Young's modulus in a direction orthogonal to the film-drawing direction (the widthwise direction)), so that the resultant primer layer of the coating composition could be 1.8 μm after dried and calendered. The above magnetic coating composition was applied on the primer layer by the wet-on-wet method, so that the resultant magnetic layer could have a thickness of 0.15 μm after subjected to an orientation treatment in a magnetic field, dried and calendered. The magnetic layer was orientated in a magnetic field and dried with a drier to give a magnetic sheet. The orientation treatment in the magnetic field was carried out by disposing N-N opposed magnets (5 kG) in front of the drier, and disposing two pairs of N-N opposed magnets (5 kG) at an interval of 50 cm and at positions 75 cm before a position where the dryness of the coating layer was felt with one's finger within the drier. The coating rate was 100 m/min.

<<Components of coating composition for backcoat layer>>

| | | |
|---|---|---|
| Carbon black (average particle size: 25 nm) | 80 | parts |
| Carbon black (average particle size: 370 nm) | 20 | parts |
| Nitrocellulose | 44 | parts |
| Polyurethane resin (containing SO₃Na groups) | 30 | parts |
| Cyclohexanone | 260 | parts |
| Toluene | 260 | parts |
| Methyl ethyl ketone | 525 | parts |

The above components of the coating composition for the backcoat layer were dispersed in a sand mill for a residence time of 45 minutes, and thereto was added polyisocyanate (13 parts) as a crosslinking agent, and the mixture was filtered to obtain the coating composition for the backcoat layer. This coating composition was applied to the other surface of the magnetic sheet reverse to the magnetic layer formed thereon so that the resultant backcoat layer could have a thickness of 0.5 μm after dried and calendered. The resultant magnetic sheet was planished with a seven-staged calender comprising metallic rolls, at 100° C. under a linear pressure of 150×9.8 N/cm (150 kg/cm). The resultant magnetic sheet (for magnetic tapes) was wound onto a core and aged at 70° C. for 72 hours.

Next, the magnetic sheet was cut into a plurality of magnetic tapes each having a width of ½ inch using a slitting system. The resultant magnetic tape was wound onto a reel and assembled in a casing body to finish a magnetic tape cartridge for use in a computer (or a computer tape)

The computer tape thus obtained was evaluated with respect to the basic properties such as reproducing output properties, error rate, servo properties, etc. Above all, off-track amount which would give serious influence on the servo properties is particularly described. The off-track amount is greatly influenced by the properties of the non-magnetic particles used in the primer layer. In this context, several comparisons for evaluating off-track amounts were made between the use of each of the plate-form oxide particles of the present invention as non-magnetic particles for the primer layer and the use of conventional needle-like a-iron oxide particles therefor. The off-track amounts of these cases were measured by the following method.

(Measurement of Off-track Amount)

Recording (at a recording wavelength of 0.55 μ) was made on a computer tape at a temperature of 10° C. and a humidity of 10% RH by using an adapted LTO drive (in which the recording track width was 20.6 μm, and the reproducing track width, 12 μm), and then, reproducing was made from the same computer tape at a temperature of 10° C. and a humidity of 10% RH, and at a temperature of 29° C. and a humidity of 80% RH, respectively, so as to calculate a reproduction ratio. The off-track amount was determined from such a reproduction ratio. In this connection, when a LTO drive having recording tracks with a width of 80 μm and reproducing tracks with width of 50 μm was used, almost no decrease in output due to off-track (1% or less) occurred.

Table 8 shows the results of the comparisons for evaluating off-track amounts which were made between the use of each of the plate-form oxide particles of the present invention as the oxide particles for the primer layer and the use of the conventional acicular α-iron oxide particles for the primer layer.

TABLE 8

| | Oxide particles used in a primer layer | | | | |
|---|---|---|---|---|---|
| | | | Particle | | Off-track |
| | Kind | Shape | size (nm) | Ex. No. | amount (%) |
| Ex. 45 | cerium | hexagonal | 32 | Ex. 3 | 2.7 |
| | oxide | to | | | |
| | | rectangle | | | |
| Ex. 46 | zirconium | hexagonal | 23 | Ex. 9 | 2.8 |
| | oxide | | | | |
| Ex. 47 | aluminum | rectangle | 38 | Ex. 15 | 1.9 |
| | oxide | | | | |
| Ex. 48 | silicon | disc-like | 22 | Ex. 22 | 2.2 |
| | oxide | | | | |
| Ex. 49 | iron | rectangle | 65 | Ex. 28 | 3.6 |
| | oxide | to | | | |
| | | hexagonal | | | |
| Ref. Ex. 1 | iron | acicular | 120 | — | 6.7 |
| | oxide | | | | |
| | (α-Fe₂O₃) | | | | |

As is apparent from Table 8, the off-track amount was smaller when the plate-form particles with a particle size of 10 to 100 10 nm according to the present invention were used as the non-magnetic oxide particles of the primer layer, as compared with the use of the conventional needle-like oxide particles.

In general, off-track does not cause so serious problems in case where the width of the recording tracks is sufficiently 15 wide. However, problems caused by off-track becomes serious as the width of the recording tracks becomes narrower. When the off-track amount is larger, an off-track error arises, and thus, it becomes impossible to carry out normal servo control. This problem occurs in common in both of the magnetic servo system and the optical servo system, of which the optical servo system is far more markedly influenced by the off-track amount, because the mass of a whole of the magnetic head array used in the optical servo system is larger than that of the magnetic head array used in the magnetic serve system.

The use of the plate-form oxide particles of the present invention makes it possible to decrease PES (a standard deviation of positional shift), and makes it hard to cause off-track even if the recording track width is as narrow as 21 μm or less and also even if a change in temperature occurs. Thus, it becomes possible to provide a magnetic tape and a magnetic tape cartridge with excellent servo properties and a lower error rate.

This may be assumed that the plate-form shapes of the particles facilitate the array of the plate-form faces of the particles in parallel to the coating surface in the coating layer, and consequently that the anisotropy of elastic modulus is small in the interior of the tape. In addition, the particles of the present invention have a small particle size of 10 to 100 nm and also have plate-form shapes, and therefore have larger surface areas. As a result, such particles can more firmly be bound with a binder, and thus can provide an excellent magnetic tape with less thermal and mechanical deformation.

In the above Examples, the use of the plate-form particles of the present invention in the primer layers are described. However, other than the primer layers, the addition of the plate-form particles of the present invention in the magnetic layers and the backcoat layers is, of course, effective. That is, when the non-magnetic oxide particles of the present invention are used in magnetic tapes by making good use of their plate-form shapes, the most distinguished feature of the present invention in contrast to the granular shapes, plate-form needle shapes or cubic shapes of the conventional non-magnetic oxide particles, the resultant magnetic tapes show far less deformation due to a change in temperature or humidity or far less mechanical deformation, and thus are optimal for high density recording.

Further, the use of the non-magnetic oxide particles of the present invention in the magnetic layer provides a magnetic tape with less thermal and mechanical deformation as mentioned above, and the magnetic layer containing such oxide particles can also act as an abrasive material as described in Examples of the abrasive tape. The action as the abrasive is more effectively exhibited as the thickness of the magnetic layer reduces. In particular, when the thickness of the magnetic layer is so thin as 0.1 μm or less, the granular or spherical particles used so far as the additive in such a magnetic layer protrude from the surface of the magnetic layer, and thus, the surface smoothness of the magnetic layer degrades. By contrast, the non-magnetic oxide particles of the present invention are plate-form shaped, having a particle size of 10 to 100 nm, and therefore, such particles do not protrude from the surface of the magnetic layer, or, even if protrude, the degree of the protrusion is far smaller in comparison with the conventional oxideparticles. Therefore, the magnetic layer according to the present invention can have excellent surface smoothness while maintaining the abrading property.

### (8) Application of the Non-magnetic Plate-form Oxide Particles to an Abrasive Liquid

Next, the application of the plate-form oxide particles of the present invention to an abrasive liquid is described.

### Example 50

A slurry-like abrasive liquid was prepared as follows by using the cerium oxide particles obtained in Example 1 as abrasive particles.

To a solution of polyammonium acrylate (3 g) in pure water (300 cc) were added the plate-form cerium oxide particles (24 g) obtained by the foregoing method, and the mixture was dispersed at 3,000 rpm for one hour with a homomixer. The resultant slurry-like abrasive liquid was very stable and showed almost no precipitate therein even after left to stand for one day.

### Example 51

A slurry-like abrasive liquid was prepared as follows by using the silicon oxide particles obtained in Example 22 as abrasive particles.

To a solution of polyammonium acrylate (3 g) in pure water (300 cc) were added the above silicon oxide particles (24 g) in the same manner as in Example 50, and a slurry-like abrasive liquid was prepared in the same manner as in Example 50. The resultant slurry-like abrasive liquid was very stable and showed almost no precipitate therein even after left to stand for one day.

### Example 52

A slurry-like abrasive liquid was prepared as follows by using the zirconium oxide particles obtained in Example 8 as abrasive particles.

To a solution of polyammonium acrylate (3 g) in pure water (300 cc) were added the above zirconium oxide particles (24 g) in the same manner as in Example 50, and a slurry-like abrasive liquid was prepared in the same manner as in Example 50. The resultant slurry-like abrasive liquid was very stable and showed almost no precipitate therein even after left to stand for one day.

### Example 53

A slurry-like abrasive liquid was prepared as follows by using the aluminum oxide particles obtained in Example 15 as abrasive particles.

To a solution of polyammonium acrylate (3 g) in pure water (300 cc) were added the above aluminum oxide particles (24 g) in the same manner as in Example 50, and a slurry-like abrasive liquid was prepared in the same manner as in Example 50. The resultant slurry-like abrasive liquid was very stable and showed almost no precipitate therein even after left to stand for one day.

### Example 54

Plate-formα-iron oxide particles obtained by the following method were used instead of the cerium oxide particles used in Example 50.

<<Preparation of plate-form a-iron oxide particles>>

An alkaline aqueous solution was prepared by dissolving sodium hydroxide (0.75 mol) and 2-aminoethanol (100 ml) in water (800 ml). Separately, an aqueous ferric chloride solution was prepared by dissolving ferric chloride (III) hexahydrate (0.074 mol) in water (400 ml). The alkaline aqueous solution and the aqueous ferric chloride solution were cooled to 5° C., and to the alkaline aqueous solution was added dropwise the aqueous ferric chloride solution under cooling so that the resultant solution was not warmed to 8° C. or higher, since this dropwise addition increased the temperature of the solution due to the heat of reaction. Thus, precipitate containing ferric hydroxide was prepared. The pH of the precipitate was 11.3. The precipitate in the state of a suspension was aged for 20 hours and then washed with water until the pH was adjusted to 7.5.

Next, the supernatant was removed, and the suspension of the precipitate was charged in an autoclave and subjected to a hydrothermal treatment at 150° C. for 2 hours.

The resultant product was filtered, dried at 90° C. in an air, lightly crushed in a mortar, and subjected to a heating treatment at 600° C. in an air for one hour to obtain α-iron oxide particles. After the heating treatment, the α-iron oxide particles were further washed with water using an ultrasonic disperser, filtered and dried so as to remove the unreacted substances and the residue.

As a result of the measurement of the X-ray diffraction spectrum of the resultant α-iron oxide particles, a spectrum corresponding to an α-hematite structure was clearly observed. The shapes of the α-iron oxide particles were further observed with a transmission electron microscope. As a result, they were hexagonal plate-form particles with a particle size of 30 to 40 nm.

<<Preparation of Slurry-like Abrasive Liquid>>

To a solution of polyammonium acrylate (3 g) in pure water (300 cc) were added the plate-form α-iron oxide particles (24 g) obtained by the above method, in the same manner as in Example 50, and a slurry-like abrasive liquid was prepared in the same manner as in Example 50. The resultant slurry-like abrasive liquid was very stable and showed almost no precipitate therein even after left to stand for one day.

### Comparative Example 17

<<Use of Cerium Oxide Particles as Abrasive Particles>>

Cerium carbonate was used as a salt of cerium instead of the cerium oxide particles (prepared in Example 1) used in Example 50, and this salt of cerium was oxidized by heating at 600° C. in an air, to obtain cerium oxide particles. The resultant cerium oxide particles were coarse particles with particle sizes of submicron, and thus were further milled in an aqueous medium with a ball mill to obtain fine particles. The resultant cerium oxide particles obtained by the milling contained from very fine particles with a particle size of 0.1 μm to particles with a particle size of 1 μm which might be the agglomerates of the primary particles. The shapes of the cerium oxide particles were mass-like and irregular.

<<Preparation of Slurry-like Abrasive Liquid>>

To a solution of polyammonium acrylate (3 g) in pure water (300 cc) were added the above cerium oxide particles (24 g) in the same manner as in Example 50, and a slurry-like abrasive liquid was prepared in the same manner as in Example 50. The resultant slurry-like abrasive liquid had unstable properties and formed precipitate in short time when dispersed and then left to stand, and the cerium oxide particles accumulated on the bottom of the container.

### Comparative Example 18

<<Use of Silicon Oxide Particles as Abrasive Particles>>

Commercially available colloidal silica was used. As a result of the observation of the colloidal silica with a transmission electron microscope, the colloidal silica particles were substantially spherical, having the particle size distribution from 10 to 100 nm.

<<Preparation of Slurry-like Abrasive Liquid>>

To a solution of polyammonium acrylate (3 g) in pure water (300 cc) were added the above colloidal silica particles (24 g) in the same manner as in Example 50, and a slurry-like abrasive liquid was prepared in the same manner as in Example 50. The resultant slurry-like abrasive liquid had considerably stable properties and formed a little precipitate after left to stand for one day.

### Comparative Example 19

<<Use of Zirconium Oxide Particles as Abrasive Particles>>

The zirconium oxide particles prepared in Comparative Example 2 were used.

A precipitate containing zirconium hydroxide was formed, and was directly washed with water without undergoing a hydrothermal treatment, filtered and dried in the same manner as in the synthesis of the zirconium oxide particles of Example 8, and the resultant particles were subjected to a heating treatment in the same manner as in Example 8 to obtain zirconium oxide particles.

As a result of the measurement of the X-ray diffraction spectrum of the resultant zirconium oxide particles, peaks corresponding to zirconium oxide were observed. The shapes of the zirconium oxide particles were observed with a transmission electron microscope. As a result, they were found to have a very wide particle size distribution which included very fine particles and coarse particles formed due to sintering or agglomeration.

The zirconium oxide particles were further milled in an aqueous medium with a ball mill to obtain fine particles. The resultant zirconium oxide particles obtained by milling had a wide particle size distribution of from 0.1 μm to 1 μm. The shapes of the zirconium oxide particles were mass-like and irregular.

<<Preparation of Slurry-like Abrasive Liquid>>

To a solution of polyammonium acrylate (3 g) in pure water (300 cc) were added the above zirconium oxide particles (24 g) in the same manner as in Example 50, and a slurry-like abrasive liquid was prepared in the same manner as in Example 50. The resultant slurry-like abrasive liquid had unstable properties and formed precipitate in short time when dispersed and then left to stand, and the zirconium oxide particles accumulated on the bottom of the container.

### Comparative Example 20

<<Use of Aluminum Oxide Particles as Abrasive Particles>>

The aluminum oxide particles prepared in Comparative Example4were used. A precipitate containing aluminum hydroxide was formed under the same conditions as those in Example 15, and washed with water in an amount about 1,000 times larger than the volume of the suspension of the precipitate, and then filtered without undergoing a hydrothermal treatment, and dried at 90° C. in an air. The solid precipitate was lightly crushed in a mortar and was subjected to a heating treatment at 600° C. in an air for one hour in the same manner as in Example 15 to obtain aluminum oxide particles. To remove the unreacted substance and the residue, the aluminum oxide particles were further washed with water using an ultrasonic disperser, and filtered and dried.

The aluminum oxide particles were milled in an aqueous medium with a ball mill to obtain fine particles. As a result of the measurement of the X-ray diffraction spectrum of the resultant aluminum oxide particles obtained by the pulverization, a spectrum corresponding to γ-alumina was observed. As a result of the observation there of with a transmission electron microscope, they had a wide particle size distribution including very fine particles with particles sizes of about 20 nm and particles with a particle size of 1 μm which might be sintered body or agglomeration of the primary particles. The shapes of the aluminum oxide particles were mass-like and irregular.

<<Preparation of slurry-like abrasive liquid>>

To a solution of polyammonium acrylate (3 g) in pure water (300 cc) were added the above aluminum oxide particles (24 g) in the same manner as in Example 53, and a slurry-like abrasive liquid was prepared in the same manner as in Example 53. The resultant slurry-like abrasive liquid had unstable properties and formed precipitate in short time when dispersed and then left to stand, and the aluminum oxide particles accumulated on the bottom of the container.

### Comparative Example 21

<<Use of α-Iron Oxide Particles as Abrasive Particles>>

Commercially available α-iron oxide particles were used.

The α-iron oxide particles of this type were sold on the market for use as abrasive particles to be added to magnetic tapes or the like. When the shapes of the particles were observed with a transmission electron microscope, they were spherical or granular, and had a narrow particle size distribution of from 0.2 to 0.3 μm.

<<Preparation of Slurry-like Abrasive Liquid>>

To a solution of polyammonium acrylate (3 g) in pure water (300 cc) were added the above a-iron oxide particles (24 g) in the same manner as in Example 50, and a slurry-like abrasive liquid was prepared in the same manner as in Example 50. The resultant slurry-like abrasive liquid had relatively stable properties and formed a little precipitate after left to stand for several hours.

### Example 55

<<Abrasive Particles Used>>

The cerium oxide particles used in Example 50 and the colloidal silica used in Comparative Example 18 were mixed for use. The mixing proportions of the cerium oxide particles and the colloidal silica particles were 70% by weight and 30% by weight, respectively.

<<Preparation of Slurry-like Abrasive Liquid>>

To a solution of polyammonium acrylate (3 g) in pure water (300 cc) were added the above cerium oxide particles (16.8 g) and the above colloidal silica (7.2 g) in the same manner as in Example 50, and a slurry-like abrasive liquid was prepared in the same manner as in Example 50. The resultant slurry-like abrasive liquid was very stable and formed almost no precipitate after left to stand for one day.

(Evaluation)

A porous abrasive pad made of a urethane resin was applied to a glass plate with a thickness of 10 mm. The slurry-like abrasive liquid prepared in each of the above Examples and Comparative Examples was added dropwise onto this pad at a rate of 10 cc/min., while a glass ball with a diameter of 6.25 mm was rotated thereon at 30 rpm under a load of 20 g for 2 minutes with a surface meter (“HEIDON-14DR” manufactured by Shintokagaku). Then, the degree of the abrasion of the glass ball, and the abrasion flaws on the surface of the glass ball were observed with a microscope, and then evaluated based on four criteria of A, B C and D as described below.

A: markedly abraded

D: hardly abraded

B and D: medium states between A and D, provided that B indicates that the abrasion degree was higher than C.

Five or more abrasion flaws on the surface of the glass ball was evaluated as D; 3 to 4 abrasion flaws thereon, as C; 2or less abrasion flaws thereon, as B; and no abrasion flaw thereon, as A. The results of the evaluation of the abrading properties are shown in Table 9.

TABLE 9

| | | | | | Abrading | |
|---|---|---|---|---|---|---|
| | | | | | property | |
| | Abrasive particles | | | Stability | Degree | Flaws |
| | | | Particle | of | of | due to |
| | Kind | Shape | size | slurry | abrasion | abrasion |
| Ex. 50 | Cerium | Hexagonal | 10 to 20 nm | Very | B | A |
| | oxide | plate | | stable | | |
| Ex. 51 | Silicon | Disc-likeplate | 30 to 40 nm | Very | B | A |
| | oxide | | | stable | | |
| Ex. 52 | Zirconium | Hexagonal | 10 to 20 nm | Very | B | A |
| | oxide | plate | | stable | | |
| Ex. 53 | Aluminum | Rectangleplate | 30 to 50 nm | Very | A | B |
| | oxide | | | stable | | |
| Ex. 54 | α-iron | Hexagonal | 30 to 40 nm | Very | B | A |
| | oxide | plate | | stable | | |
| Ex. 55 | Cerium | Hexagonal | 0 to 20 nm | Very | B | A |
| | oxide & | plate & | & 10 | stable | | |
| | Silicon | spherical | to 100 nm | | | |
| | oxide | | | | | |
| Com. Ex. | Cerium | Irregular | 0.1 to 1 μm | Unstable | C | C |
| 17 | oxide | | | | | |
| Com. Ex. | Silicon | Spherical | 10 to | Stable | B | B |
| 18 | oxide | | 100 nm | | | |
| Com. Ex. | Zirconium | Irregular | 0.1 to 1 μm | Unstable | B | D |
| 19 | oxide | | | | | |
| Com. Ex. | Aluminum | Irregular | 20 nm to | Unstable | A | D |
| 20 | oxide | | 1 μm | | | |
| Com. Ex. | α-iron | Spherical | 0.2 to | Relatively | C | C |
| 21 | oxide | | 0.3 μm | stable | | |

It is seen from the results of Table 9 that the slurry-like abrasive liquids of the above Examples are very stable. This is because the particle sizes thereof are as small as several tens nanometers, and also because they are abrasive particles which show almost no sintering or agglomeration and thus have very excellent dispersibility. In addition, their abrading properties are good despite of their small particle sizes. This is because the edge portions of the particles are increased because of their plate-form shapes, resulting in improved abrading power. Although some of the particles of Examples are slightly lower in abrading power, their abrading power is considered to be further improved, if the conditions such as the number of rotations, loads to be applied, etc. are optimized for the abrasive liquids.

Further, no flaw due to the abrasion is caused by any of the abrasive liquids of Examples, since their particle sizes are so small as several tens nanometers and also have narrow particle size distributions. Therefore, no abrasion flaw is caused by such coarse particles that would be often mixed in the very fine particles of the conventional abrasive members.

On the other hand, the abrasive liquid of Comparative Example 18 using the colloidal silica are relatively good in abrading power and in the number of abrasion flaws, and thus is well balanced. However, as compared with the abrasive liquid of Example 51 using the silicon oxide particles of the same kind, the abrasive liquid of Comparative Example 18 is inferior as a whole.

The abrasive liquid of Comparative Example 21 using the α-iron oxide particles is considered to be relatively well balanced. However, higher abrading power can not be expected from this abrasive liquid, because the hardness of iron oxides themselves is intrinsically low. By contrast, the abrasive liquid of Example 54 using the α-iron oxide particles are greatly improved in abrading power and in the number of abrasion flaws, as compared with the abrasive liquid of Comparative Example 21, since the edge portions of the abrasive particles of this Example are increased because of their plate-form particle shapes.

The abrasive liquid of Comparative Example 17 using the cerium oxide particles is relatively well balanced in abrading properties, but is unsatisfactory as a whole. By contrast, the abrasive liquid of Example 50 using the cerium oxide particles of the same kind is greatly improved in abrading power and in the number of the abrasion flaws, and thus, it is seen that the plate-form cerium oxide particles of this Example are especially suitable for the slurry-like abrasive liquid.

The abrasive liquid of Comparative Example 19 using the zirconium oxide particles and the abrasive liquid of Comparative Example 20 using the aluminum oxide particles are relatively high in abrading power, but cause lots of abrasion flaws. This is because the hardness of zirconium oxide and aluminum oxide are intrinsically high, and also because it is considered that the coarse particles mixed in the zirconium oxide particles and the aluminum oxide particles of Comparative Examples caused the lots of abrasion flaws. By contrast, the abrasive liquid of Example 52 using the plate-form zirconium oxide particles and the abrasive liquid of Example 53 using the plate-form aluminum oxide particles exhibited excellent abrading power without causing abrasion flaws, because of their plate-form shapes with very small particle sizes and their very narrow particle size distributions.

Furthermore, as shown in Example 55, the use of the mixture of the plate-form particles of the present invention and the general-purpose abrasive particles makes it possible to provide abrasive members capable of flexibly corresponding to a variety of articles to be polished.

### (9) Other Applications

The non-magnetic plate-form particles of the present invention can be applied to not only abrasive tapes, magnetic tapes and abrasive liquids, but also various types of functional optical films such as antireflection films, UV- or infrared-shielding films, etc. Specifically, the non-magnetic plate-form particles (particularly oxide particles) are easy to array with their plate-form faces in parallel to the surface of a film because of their plate-form shapes. As a result, the light transmission through the film is improved. That is, when light transmits the non-magnetic plate-form particles in the film, the inherent properties of the non-magnetic plate-form particles are fully exhibited due to the interaction between light and the non-magnetic plate-form particles.

For example, the lamination of a layer of the plate-form silicon oxide particles having a low refractive index and a layer of the plate-form zirconium oxide particles having a high refractive index provides a high performance antireflection film having a very high transparency which has not been obtained from the conventional granular or spherical oxide particles. Further, the use of the plate-form iron oxide particles makes it possible to provide an UV-screening film having a high transmittance. Furthermore, when a high density coating film is formed from a mixture of the plate-form zirconium oxide particles and the plate-form cerium oxide particles both of which have high refractive indexes, by making good use of their plate-form shapes, the resultant coating film is transparent and has a very high refractive index, comparable to a film formed by sputtering, although it is formed by coating.

### Effect of the Invention

As has been fully described above, according to the processes of the present invention, there can be provided plate-form shaped non-magnetic particles with a particle size of 10 to 100 nm in the plate-form face directions, specifically the plate-form particles of oxides such as cerium oxide, zirconium oxide, aluminum oxide, silicon oxide, iron oxide, etc., which hitherto have not been obtained by any of the conventional processes. The non-magnetic plate-form particles, particularly the plate-form oxide particles, of the present invention have a uniform particle size distribution and rarely suffer from sintering or agglomeration thereof, thus having a good crystallinity. The application of such non-magnetic plate-form particles of the present invention to, for example, abrasive tapes, abrasive sheets, abrasive films and abrasive members of abrasive tools, functional optical films such as magnetic tapes, etc. greatly improves the properties thereof, as compared with the application of the conventional oxide particles thereto. As is understood from the above, it is expected that the non-magnetic plate-form particles of the present invention will find quite novel uses or applications which are believed to be impossible so far.

1. Non-magnetic plate-form oxide particles wherein a particle has a plate-form shape, and a particle size is from 10 nm to 100 nm in the plate direction of the particle.

2. (Cancelled)

3. The non-magnetic plate-form oxide particles according to claim 1, wherein said oxide particles are at least one kind of oxide particles selected from the group consisting of cerium oxide particles, zirconium oxide particles, aluminum oxide particles, silicon oxide particles and iron oxide particles.

4. The non-magnetic plate-form oxide particles according to claim 1, wherein said oxide particles are at least one kind of oxide particles selected from the group consisting of cerium oxide particles, zirconium oxide particles, aluminum oxide particles and silicon oxide particles.

5. The non-magnetic plate-form oxide particles according to claim 1, wherein said oxide particles are iron oxide particles at least 50% of which have pores in the thickness direction of the particles.

6. The non-magnetic plate-form oxide particles according to any one of claims 1 and 3 to 5, wherein the shape of the particle is a polygon.

7. The non-magnetic plate-form oxide particles according to claim 6, wherein the shape of the particle is a hexagon.

8. The non-magnetic plate-form oxide particles according to claim 6, wherein the shape of the particle is a rectangle.

9. The non-magnetic plate-form oxide particles according to claim 1, 3 or 4, wherein the shape of the particle is a disc or an elliptic plate.

10. An abrasive comprising non-magnetic plate-form oxide particles according to any one of claims 1 and 3 to 5.

11. A method for producing non-magnetic plate-form oxide particles according to claim 1, comprising the steps of:
(1) adding an aqueous solution of a metal salt or a non-metal salt to an alkaline aqueous solution to form a hydroxide or a hydrate of a metal or a non-metal element,
(2) aging the hydroxide or hydrate of the metal or non-metal element obtained in the step (1), and
(3) heating the aged hydroxide or hydrate of the metal or non-metal element at a temperature of 110 to 300° C. in the presence of water.

12. A method for producing non-magnetic plate-form oxide particles according to claim 1, comprising the steps of:
(1) adding an aqueous solution of at least one metal or non-metal salt selected from the group consisting of cerium salts, zirconium salts, aluminum salts, silicon salts and iron salt to an alkaline aqueous solution to form a hydroxide or a hydrate of a metal or a non-metal element,
(2) aging the hydroxide or hydrate of the metal or non-metal element obtained in the step (1), and
(3) heating the aged hydroxide or hydrate of the metal or non-metal element at a temperature of 110 to 300° C. in the presence of water.

13. A method for producing non-magnetic plate-form oxide particles according to claim 1, comprising the steps of:
(1) adding an aqueous solution of at least one metal salt or non-metal salt selected from the group consisting of cerium salts, zirconium salts, aluminum salts, silicon salts and iron salt to an alkaline aqueous solution to form a hydroxide or a hydrate of a metal or a non-metal element,
(2) aging the hydroxide or hydrate of the metal or non-metal element obtained in the step (1),
(3) heating the aged hydroxide or hydrate of the metal or non-metal element at a temperature of 110 to 300° C. in the presence of water, and
(4) filtering and drying the product obtained in the previous heating step and then further heating the product at a temperature of 300 to 1200° C. in an air.

14. The method for producing non-magnetic plate-form oxide particles according to claim 13, which further comprises a step of removing products other than the desired oxide or residual materials by washing with water after the further heating step at a temperature of 300 to 1200° C. in an air.

15. The method for producing non-magnetic plate-form oxide particles according to any one of claims 12 to 14, wherein pH of a suspension after the formation of the hydroxide or hydrate of the metal or non-metal element in the step of adding the aqueous solution of the salt to the alkaline aqueous solution is adjusted in a range from 8 to 12.

16. The method for producing non-magnetic plate-form oxide particles according to claim 11, which further comprises a step of washing the hydroxide or hydrate of the metal or non-metal element with water to remove products other than the desired oxide or residual materials, and a step of readjusting pH of a suspension in a rage from 7 to 10, between the step of adding the aqueous solution of the salt to the alkaline aqueous solution and the step of heating the hydroxide or hydrate of the metal or non-metal element at a temperature of 110 to 300° C. in the presence of water.

17. The method for producing non-magnetic plate-form oxide particles according to claim 11, which further comprises a step of adjusting pH of the suspension containing the product in a rage from 6 to 9 after the step of heating the hydroxide or hydrate of the metal or non-metal element at a temperature of 110 to 300° C. in the presence of water.

18. The method for producing non-magnetic plate-form oxide particles according to claim 11, which further comprises a step of treating the product with a silicon compound after the step of heating the hydroxide or hydrate of the metal or non-metal element at a temperature of 110 to 300° C. in the presence of water.

19. The method for producing non-magnetic plate-form oxide particles according to claim 11, wherein said alkaline aqueous solution contains a hydroxyalkylamine.

20. An abrasive member comprising a support and an abrasive layer which is formed on said support and which comprises a binder and an abrasive dispersed in the binder, wherein said abrasive comprises the non-magnetic plate-form oxide particles according to claim 1.

21. An abrasive liquid comprising a medium and the non-magnetic plate-form oxide particles according to claim 1 which are dispersed in said medium.

22. The abrasive liquid according to claim 21, which further comprises colloidal silica particles.
